(19) United States
(12) Patent Application Publication
(10) Pub. No.: US 2015/0228917 A1
(43) Pub. Date: Aug. 13, 2015

(54) Optoelectronic Devices Based on Heterojunctions of Single-Walled Carbon Nanotubes and Silicon

(71) Applicant: NORTHEASTERN UNIVERSITY, Boston, MA (US)

(72) Inventors: Yung Joon Jung, Lexington, MA (US); Swastik Kar, Belmont, MA (US); Young Lae Kim, Stoneham, MA (US); Hyun Young Jung, Malden, MA (US); Young Kyun Kwon, Seoul (KR)

(21) Appl. No.: 14/428,398

(22) PCT Filed: Sep. 19, 2013
(86) PCT No.: PCT/US13/60666

§ 371 Date: Mar. 16, 2015

Related U.S. Application Data
(60) Provisional application No. 61/702,807, filed on Sep. 19, 2012.

(51) Int. Cl. H01L 51/42

(52) U.S. Cl. CPC H01L 51/4213; H01L 2031/0344

(57) ABSTRACT

Heterojunctions of single-walled carbon nanotubes and p-doped silicon produce a photocurrent when irradiated with visible light under reverse bias conditions. In optoelectronic devices utilizing the heterojunctions, the output current can be controlled completely by both optical and electrical inputs. The heterojunctions provide a platform for heterogeneous optoelectronic logic elements with high voltage-switchable photocurrent, photo-voltage responsivity, electrical ON/OFF ratio, and optical ON/OFF ratio. The devices are combined to make switches, logic elements, and imaging sensors. An assembly of 250,000 sensor elements on a centimeter-scale wafer is also provided, with each sensor element having a heterojunction of single-walled carbon nanotubes and p-doped silicon, and producing a current dependent on both the optical and the electrical input.

### CROSS REFERENCE TO RELATED APPLICATIONS

This application claims the benefit of provisional application Ser. No. 61/702,807 filed Sep. 19, 2012 and entitled “PHOTORESPONSE IN HETEROJUNCTION STRUCTURE OF SINGLE WALLED CARBON NANOTUBES AND SILICON FOR OPTOELECTRONIC APPLICATIONS”, which is hereby incorporated herein by reference in its entirety.

### STATEMENT REGARDING FEDERALLY SPONSORED RESEARCH OR DEVELOPMENT

The invention was developed with financial support from Grant No. ECCS-1202376 from the National Science Foundation. The U.S. Government has certain rights in the invention.

### BACKGROUND

Significant progress has been made in the development of silicon-based photonic circuit components such as on-chip sources, manipulators, detectors, storage, filtering, and multiplexing technologies which are compatible with the microelectronics platform. (Almeida et al., 2004; Vlasov et al., 2001; Vlasov et al., 2005; Liu et al., 2010; Rong et al., 2005; Hofmann et al., 2012; Michel et al., 2010; and Bogaerts et al., 2010). A successful integration of the low-loss photonics-based data transfer technology with the performance of ultrafast logic and memory elements of conventional integrated circuits could render possible new generations of microprocessors with significantly improved performances. (Liang et al., 2010; Lee et al., 2011; CMOS compatible optical interconnects, 2011; and Hofstein et al., 1963). An important component of this heterogeneous integration is the development of monolithic logic elements which can operate with both electrical and optical inputs. Historically, logic operations in electronic circuits have been achieved by field-effect transistors (Hofstein et al., 1963; Bertrand et al., 2004), while switching in photonic circuits has been achieved by methods such as second harmonic generation in non-linear optical material (Stegeman et al., 1996) and optomechanical resonance techniques (Weis et al., 2010).

Given the technological dissimilarity between electronic and optical logic elements, seamless integration of these two on a single chip is challenging and has not been achieved previously. Thus, there remains a need for a monolithic hybrid device, whose output depends on both optical and electrical inputs.

### SUMMARY

One aspect of the invention is a heterojunction that includes a plurality of single-walled carbon nanotubes (SWNT) disposed on a first surface region of a p-doped Si material, the heterojunction capable of generating a photocurrent under reverse bias conditions and in response to irradiation of the heterojunction with electromagnetic radiation, such as visible light. In a related embodiment, a heterojunction between a single SWNT and p-doped Si is provided.

In a related embodiment, the heterojunction includes a second surface region of the p-doped Si material surrounding the first surface region, the second surface region covered by an insulating layer, such that the SWNT extend from the first surface region onto the second surface region where they are separated from the p-doped Si material by the insulating layer. For example, the SWNT are configured as a belt extending from the first surface region to the second surface region, the belt having a width in the range from about 0.1 mm to about 500 nm. For example, the belt is attached to an electrical contact disposed on the insulating layer. The belt of SWNT can be fabricated using template-guided fluidic assembly, wherein the SWNT are deposited into a lithographically-produced trench having a hydrophilic bottom and hydrophobic sides and upper surface; the trench width determines the width of the SWNT belt.

In another related embodiment, SWNT are configured as a patch overlaying said first surface region, the patch peripherally overlaying a portion of the second surface region. The SWNT patch can be fabricated using template-guided fluidic assembly, in which the SWNT are deposited into a pit having a hydrophilic bottom and hydrophobic sides and upper surface.

According to certain embodiments the insulating layer includes or consists of silicon dioxide. For example, the insulating layer has a thickness of from about 100 nm to about 400 nm.

In related embodiments, the photocurrent is generated in response to visible light incident on the SWNT, the light having a wavelength from about 300 nm to about 800 nm. For example, light incident on the SWNT is of an intensity of about 117 microwatts or less. Embodiments include a heterojunction such that the photocurrent is generated when a reverse bias voltage of from about 0.1 to about 3 volts is applied across the heterojunction. In alternative embodiments the photocurrent is generated when a reverse bias voltage of from about 0.1 to about 4 volts is applied across the heterojunction. For example, the reverse bias voltage applied is from about 0.1 to about 1 volts, or about 1 to about 2 volts, or about 2 to about 3 volts, or about 3 to about 4 volts. According to other embodiments, photocurrent is only generated when a reverse bias voltage of from about 0.1 to about 3 volts is applied across the heterojunction.

According to other related embodiments, the Si is p-doped with boron at a level from about 10¹⁴ to about 10¹⁷ atoms/cm³. For example, the Si is doped with boron in an amount of about 10¹⁴ to about 10¹⁶ atoms/cm³, about 10¹⁵ to about 10¹⁶ atoms/cm³, or about 10¹⁶ to about 10¹⁷ atoms/cm³. Alternatively, the Si is p-doped with phosphorus, arsenic, gallium, aluminum, or a mixture thereof.

In certain embodiments of the above heterojunctions, the heterojunction is fabricated by a process including template-guided fluidic assembly.

Another aspect of the invention is a device including a heterojunction according to any of the above embodiments, a first electrical contact ohmically connected to the SWNT, and a second electrical contact ohmically connected to the p-doped Si material, wherein an output current flowing between the first and second contacts and through the heterojunction is modulated by both an optical input and an electrical input. For example, the electrical input is a reverse bias voltage applied between the first and second contacts. For example, the optical input is light incident on the SWNT.

In related embodiments of the invention the device is configured to accept the incident light from a solid state light emitter or a light guide. Related embodiments include a device that requires both an optical input and an electrical input to generate a photocurrent at the heterojunction. In certain related embodiments the device functions as a mixed optoelectronic AND gate. In certain embodiments, the device includes a plurality of the heterojunctions.

In other related embodiments the device functions as a 2-bit optoelectronic ADDER/OR gate, the device including first and second heterojunctions, such that the first heterojunction is connected to the first electrical contact by a first SWNT belt and the second heterojunction also is connected to the first electrical contact by a second SWNT belt, such that the first and second SWNT belts have essentially the same width, and illumination of the first and/or second SWNT belts with application of a reverse bias between the first and second electrical contacts generates a photocurrent that is proportional to the total number of illuminated SWNT belts.

In related embodiments the device further comprises first and second solid-state lasers configured to illuminate said first and second SWNT belts, respectively.

According to another related embodiment, the device functions as a 4-bit optoelectronic digital-to-analog converter, the device including first, second, third, and fourth heterojunctions, wherein the first heterojunction is connected to the first electrical contact by a first SWNT belt, the second heterojunction also is connected to the first electrical contact by a second SWNT belt, the third heterojunction also is connected to the first electrical contact by a third SWNT belt, and the fourth heterojunction also is connected to the first electrical contact by a fourth SWNT belt, such that the second SWNT belt has a width essentially two times the width of the first SWNT belt, the third SWNT belt has a width essentially four times the width of the first SWNT belt, and the fourth SWNT belt has a width essentially eight times the width of the first SWNT belt, and such that the illumination of the first and/or second and/or third and/or fourth SWNT belts and application of a reverse bias between the first and second electrical contacts generates a photocurrent that is proportional to the total width of the illuminated SWNT belts.

In related embodiments, the device further includes first, second, third, and fourth solid-state lasers configured to illuminate said first, second, third, and fourth SWNT belts, respectively.

According to another embodiment, the device including a heterojunction, a first electrical contact connected to the SWNT, and a second electrical contact connected to the p-doped Si material, functions as a bidirectional phototransistor, and further includes a plurality of first heterojunctions and a plurality of second heterojunctions disposed on a common p-doped Si surface, such that the first heterojunctions are connected via a first SWNT belt set to a first electrical contact disposed on a first insulating layer on a first side of the common p-doped Si surface and the second heterojunctions are connected via a second SWNT belt set to a second electrical contact disposed on a second insulating layer on a second side of the common p-doped Si surface, the first and second insulating layers disposed opposite to each other, such that the first and second SWNT belt sets are disposed in an interdigitated configuration on the common p-doped Si surface, wherein illumination of the first and second SWNT band sets and application of a bias between the first and second electrical contacts produces a photocurrent.

In related embodiments the photocurrent is modulated by the illumination intensity. Related embodiments include devices further including a light source configured to illuminate the first and second heterojunctions.

Another embodiment of the invention is a compound device comprising a plurality of individual devices according to several of the embodiments above on a single chip. For example, the plurality of devices are configured as an array. For example, the compound device functions as an image sensor. For example, the array is about 12 mm×12 mm in size and contains about 250,000 of said devices. For example, individual devices have dimensions of about 15 μm×15 μm.

Another embodiment of the invention is a method of fabricating the heterojunction according to the embodiments above, the method including the steps of: providing a p-doped Si substrate having a surface covered with an insulating layer; producing one or more first surface regions of exposed p-doped Si by selectively removing the insulating layer using lithography and a second surface region surrounding each first surface region, the second surface regions retaining the insulating layer; etching the first and second surface regions using a plasma, whereby the first and second surface regions become hydrophilic; depositing a hydrophobic mask layer over the first and second surface regions; patterning the hydrophobic mask layer by lithography, whereby one or more microscale or nanoscale trenches or patches are formed; submerging the substrate in an suspension of SWNT; withdrawing the substrate up through the SWNT suspension, whereby SWNT are selectively deposited in the trenches or patches to form one or more heterojunctions between the deposited SWNT and the first surface regions of p-doped Si; and optionally removing the hydrophobic mask layer.

In related embodiments, the method further includes depositing a first electrical contact in ohmic connection with the deposited SWNT in the second surface region and a second electrical contact in ohmic connection with the p-doped Si in the first surface region. For example, the first and second electrical contacts comprise one or more metals selected from the group consisting of gold, titanium, and combinations thereof, such as a Ti/Au alloy. For example, the hydrophobic mask comprises poly(methyl methacrylate). In certain embodiments, any of the above described heterojunctions includes SWNT that are semiconducting, or SWNT that are exclusively semiconducting. In certain embodiments, any of the above described devices includes SWNT that are semiconducting, or SWNT that are exclusively semiconducting.

### BRIEF DESCRIPTION OF THE DRAWINGS

FIG. 1A is a schematic diagram of an exemplary monolithic optoelectronic device having heterojunctions of single-walled carbon nanotubes (SWNT) in the form of belts (107 and 108; two parallel belts are shown, but one or more can be employed in any desired configuration), and p-doped silicon present in the silicon (Si) layer (102). One end of each SWNT belt is connected to a contact (109) for electrical output. The contact for the electrical output is attached to an insulating layer, such as a layer of SiO₂ (101). An SWNT belt may be illuminated at a spot (105) by a beam of light (104) coming from a light source (103) which can be part of the device or separate. Another contact (106) is attached to the Si layer. A reverse bias can be applied between the two contacts 106 and 109 using a circuit that is part of the device or separate.

FIG. 1B is a schematic diagram of an exemplary set of four sensors, configured as an array, each having a heterojunction of single-walled carbon nanotubes (SWNT) overlaid on a layer of p-type Si. The exposed Si surface (112) is exposed by etching SiO₂ from a layer of SiO₂ (111) overlaid on a layer of p-doped Si. The exposed layer of Si is surrounded by a portion of the SiO₂ layer (111). An ohmic contact (110) is deposited as a metal layer on the SiO₂ layer and in this configuration surrounds the SiO₂ layer portion and its enclosed p-type Si surface. Contacts 110 can be connected to conductive pathways (not shown) to provide electrical access to individual sensors. Another ohmic contact (not shown) is attached to the Si layer on the side opposite to that deposited with SWNT, and provides connection for applying a reverse bias across the junctions individually or in any combination.

FIG. 2A is a schematic diagram of a monolithic optoelectronic device (2 cm×2 cm) having a heterojunction of single-walled carbon nanotubes (configured as an SWNT belt) and p-doped silicon on a silicon wafer, and two ohmic contacts (labeled “B” and “C” at FIG. 2A, right side). The device produces photocurrent in response to incident light under the application of reverse bias between contacts B and C. Shown to the left for comparison is a metal-semiconductor “Schottky-barrier” junction.

FIG. 2B is a digital photograph of heterojunctions of three SWNT belts on a p-doped silicon substrate with electrical contacts. The rectangle in the upper half includes an SiO₂ insulating layer between the p-doped Si substrate and the SWNT belts.

FIG. 2C is an SEM image of a submicron-width fluidically assembled SWNT belt.

FIG. 2D shows the current produced by a device having heterojunctions of SWNT and p-doped silicon as a function of a reverse bias voltage and illumination. The uppermost curve, and the curve extending upwards from the bottom left corner correspond, respectively, to current with no illumination (Dark), and that with visible light illumination (Photo-IV; 117 μW broadband) produced by a typical SWNT/Si heterojunction. The Photo-IV curve of an Au/Ti/Si junction (Schottky barrier) of similar dimensions and illumination condition is also shown (curve with sharply upward slope at positive bias) for comparison. Inset: Comparison of the photocurrent data with a model describing the number of accessible states for photoexcited carriers, n.

FIG. 2E is a graph of photocurrent responsivity I_{P}/P at a given voltage (bottom curve; P is the intensity of incident light), electrical ON/OFF ratio I_{P}(V)/I_{P}(V=0) (uppermost curve), and optical ON/OFF ratio=I_{P}/I_{dark} at voltage V (middle curve) of the SWNT/Si junction as a function of the reverse bias V.

FIG. 2F is a graph of IV (current-voltage) curves under dark and illumination conditions, and shows the change in open-circuit voltage under 1 μW illumination.

FIG. 3A is digital photograph of a 0.25 megapixel array of SWNT/Si optoelectronic devices or sensors (array area 12 mm×12 mm).

FIG. 3B is a magnified view of the array shown in FIG. 3A showing a large number of individual devices.

FIG. 3C is a magnified view of a section of the array of FIG. 3A showing four individual devices of the array. The central circular window is the area of exposed p-type silicon. The dashed line indicates the outer border of the area of deposited SWNT, which cover the exposed Si window and the SiO₂ insulating layer surrounding the Si window; the deposited SWNT patch is covered at its periphery by the square ring-shaped Au/Ti contact.

FIG. 3D is an SEM image of the “core” of the sensor, showing a circular window of exposed p-type Si in a SiO₂/Si substrate; the entire area shown is overlaid with SWNTs. Inset: high magnification SEM image of the SWNT packing on the Si surface.

FIG. 3E is a scanning photocurrent map of a 2×2 pixel area of the sensor array shown in FIG. 3A, where the pixels were each electrically attached to a common external lead, while an ohmic contact on the back surface of the Si substrate was used for applying reverse bias.

FIG. 4A is a bi-directional phototransistor constructed using interdigitated SWNT belts deposited on a p-doped silicon surface. One set of the SWNT belts is connected to a source contact, and another set of SWNT belts is connected to a drain contact as indicated. The contacts are affixed to the SiO₂ layers present on either side of the central silicon layer. The SWNT belts on each side are arranged in parallel, separated sufficiently to allow interdigitation of the two sets of belts without the belts touching, i.e., with open p-type Si surface between SWNT belts from each side.

FIG. 4B is a hybrid logic gate device constructed using an SWNT belt in contact with p-doped silicon. The device functions as an AND gate with both optical and electrical inputs, and an electrical output. The inset tabulates a typical set of operating conditions determining the “low” and “high” logic states for both input and output conditions.

FIG. 4C shows IV curves obtained in the operation of the hybrid logic gate shown in FIG. 4B. The upper and lower curves correspond to illuminated and dark conditions, respectively.

FIG. 4D is a graph of IV curves obtained in the operation of the bi-directional phototransistor of FIG. 4A under dark and illuminated conditions. The curves show photo-induced ON and OFF states. In the dark condition the IV curve is essentially flat, remaining at zero current for all voltages tested. Under illumination, a nonlinear current flows at both polarities, which corresponds to the reverse bias-supported photocurrent from each side of the device.

FIG. 4E shows the electrical output (Iₒᵤₜ) of the AND gate shown in FIG. 4B as a function of time. The input logic state shown on the y-axis is a combination of input 1 (light) and input 2 (voltage).

FIG. 5A is a schematic diagram of a voltage switchable two-bit adder having two identically fabricated SWNT/Si structures for providing independent optical inputs for an optoelectronic ADDER element. Two 650 nm lasers independently illuminate the SWNT structures to generate the two optical/digital inputs. The electrical output I_{OUT} is an analog electrical output signal which is proportional to the sum of the two digital inputs.

FIG. 5B is a graph of I_{OUT} as a function of time for different input configurations under an applied reverse bias. The grey and black dots indicate the ON and OFF states, respectively, of the two optical inputs. The output current shows a striking response-reproducibility for independent illumination of the two structures. The current doubles when both inputs are simultaneously illuminated.

FIG. 5C is a schematic diagram of an exemplary optoelectronic architecture, a 4-bit optoelectronic digital to analog converter. The converter relies on the high response reproducibility demonstrated in FIG. 5B. In this architecture, each successive input has twice the number of (identical) SWNT belts as the previous, corresponding to successive bit-significance as shown. An alternative to increasing the number of SWNT belts of identical width is to use single belts of increasing width, where the width of each successive belt is twice that of the previous belt.

FIG. 5D is a graph of analog current output I_{OUT} (x-axis) corresponding to digital optical inputs ranging from binary 0000₂ (0₁₀)-1111₂ (15₁₀). In both cases (FIGS. 5A and 5C) I_{OUT} can be completely tuned OFF by turning OFF the reverse bias.

FIG. 6. is a schematic diagram showing the SWNT-Si structures divided into three regions, the SWNT electrode (left), Si-SWNT interface (middle), and Si layer (right), to facilitate semi-quantitative modeling.

FIG. 7A is a schematic diagram of a (6,2) SWNT of 5.65 diameter having a lattice constant of 15.360 Å along the tube axis. FIG. 7B is a graph of the calculated electronic band structure of the (6,2) SWNT near the Fermi level (E_{F}) band-gap (E=0.662 eV). FIG. 7C is a graph of density of states of the (6,2) SWNT.

FIG. 8A is a schematic diagram of the relaxed structure of a (6,2) SWNT at one SWNT per supercell, a 1-(6,2) CNT. FIGS. 8B and 8C show the calculated band structure of the 1-(6,2) CNT on Si(100)-p4×4. The optimized structure has a reduced band gap of about 0.025 eV.

FIG. 9A is a schematic diagram of the relaxed structure of (6,2) SWNT at three SWNT per supercell, a 3-(6,2) CNT. FIGS. 9B and 9C show the calculated band structure of 3-(6,2) CNT on Si(100)-p4×4. The optimized structure has a band gap which is slightly increased compared to the 1-(6,2) CNT (FIG. 8C).

FIG. 10A shows the calculated band structure of a 1-(6,2) CNT (right) showing local Density of States (DoS) below Fermi level. FIG. 10B shows the calculated band structure of a 3-(6,2) CNT (right) showing local DoS of states below Fermi level.

FIG. 11 is a graph of cumulative DoS (CDoS=Σ_{m,n}D_{m,n}(ε)) of selected d≈1 nm SWNTs (with chirality values (m,n)). The number of accessible states in SWNTs, n[eVᵣ]=∫CDoS(ε)dε, integrated between ε=0 and ε=eVᵣ (Vᵣ=reverse bias).

FIG. 12 is a schematic energy-level diagram of Si undergoing photoexcitation, adjacent to a narrow layer of (6,2) SWNTs, followed by the cumulative DoS (CDoS=Σ_{m,n}D_{m,n}(ε)) of selected d≈1 nm SWNTs (with chirality values (m,n) as shown in figure FIG. 11). The photocurrent (corresponding to the carriers shown moving from Si to the SWNT having ε greater than 0) is due to injected electrons from Si into SWNTs and is limited by the (reverse bias dependent) number of accessible states in SWNTs, n[eVᵣ]=∫CDoS(ε)dε, integrated between ε=0 and ε=eVᵣ (Vᵣ=reverse bias), as shown.

FIG. 13 is a graph of current density plotted against voltage. The individual curves show variation of current density in the SWNT/Si junctions as a function of incident power.

FIG. 14 is a graph of photocurrent ON/OFF ratio in the SWNT/Si junction plotted against voltage. The individual curves show variation of photocurrent as a function of incident power.

FIG. 15 is a graph of photocurrent plotted against reverse bias voltage showing variation of photocurrent with reverse bias for a range of broadband and monochromatic light sources. The uppermost curve represents the situation in which there are more photoexcited carriers than accessible states, and the number of the photoexcited carriers increases with increasing reverse bias. Hence, the photocurrent increases with bias. The remaining curves represent situations in which all photoexcited carriers are accommodated within accessible states, and the reverse bias cannot increase photocurrent.

### DETAILED DESCRIPTION OF THE INVENTION

Optoelectronic devices having heterojunctions of single-walled carbon nanotubes (SWNT) and lightly p-doped Si are described herein. The heterojunctions of the invention produce a photocurrent when irradiated with visible light under reverse bias conditions. The heterojunctions are scalable, and the output current of a device having the heterojunctions is a function of both the optical and the electrical inputs. These devices possess an unconventional photo-response that results in extremely high photo-induced ON/OFF ratios at low reverse-bias voltages. The heterojunctions and devices are fabricated using the technique of template-guided fluidic assembly (Jaber-Ansari et al., 2008; Xiong et al., 2007; Kim et al., 2009). A range of multifunctional optoelectronic switches, photo-transistors, optoelectronic logic gates, and complex optoelectronic digital circuits can be made with the heterojunctions of the invention, and are suitable for analog and digital sensing, imaging, and other applications.

Conventional semiconductor heterojunction photodetectors are popular due to their broad spectral responsivity, excellent linearity, and high dynamic range of operation. In addition, they are highly suitable for scaled-up manufacturing, for example in arrays of pixels for imaging purposes (e.g. in digital cameras). In most cases, conventional photodetectors function as p-n, p-i-n, or Scottky photodiodes. In a reverse-bias condition, the reverse current saturates and becomes voltage-independent, and is usually linearly related to the incident photon flux. In this mode, the junctions are usually quite linear over a large range of incident optical power, and are excellent for optical power meters.

However, the linear response to incident light limits their ability to render high ON/OFF ratio switches. Optoelectronic photo switches are also key elements of digital optoelectronic circuits that require high ON/OFF ratios at low optical incident power levels. Devices that can change their output current by orders of magnitude at low incident light powers (resulting in high ON/OFF ratios), potentially through sharply non-linear responses, are desirable as photoswitches. The linear photoresponse in conventional photodiodes and their voltage-independent reverse current results in low ON/OFF ratios, which is a limitation on the use of the photodiodes in optoelectronic integrated circuits. Therefore, a device which demonstrates a low dark reverse-bias current, and responds with very high reverse photocurrents (equal or more than the forward bias currents) at very low reverse bias values, as described here, serves as a very effective photo-switch.

Graphene-based photo-switching devices exhibit ultrafast and broadband response. (Xia et al., 2009; Muller et al., 2013; Echtermeyer et al., 2011; Liu et al., 2011; Gabor et al., 2011; Park et al., 2009; Sun et al., 2012; Engel et al., 2012; Furchi et al., 2012; Xu et al., 2010). A key limitation of photodetectors that use graphene as the photoabsorber is their low photocurrent (Iₚₕ) responsivity R(λ)=Iₚₕ/P, (where P is the power of incident light) primarily due to the intrinsically low optical absorption (about 2.3%) of graphene. (Nair et al., 2008). Within the visible to telecommunications-friendly wavelength range (i.e. 400 nm≦λ≧1550 nm), using both photovoltaic (Xia et al., 2009; Park et al., 2009), and photo-thermoelectric or hot-carrier effects (Gabor et al., 2011; Sun et al., 2012; Xu et al., 2010) along with enhancement techniques including asymmetric metal-contacts (Muller et al., 2013), plasmonic architectures (Echtermeyer et al., 2011; Liu et al., 2011) and micro-cavity confinements (Engel et al., 2012; Furchi et al., 2012), R(λ) obtained has at best remained limited within 1−2×10⁻² A/W.

By using graphene as the carrier collector and multiplier, an effective gain mechanism (with R(λ)>10⁷ A/W) was recently reported in graphene/quantum-dot hybrid devices. (Konstantatos et al., 2012). Despite their appeal for ultra-weak signal detection, the responsivity of these devices above P=10⁻¹³ W fall as R(λ)˜1/P, implying a rapid photocurrent saturation (and hence becoming insensitive to light powers) above these weak incident powers. With considerably large dark currents that render them ineffective as photoswitches (ON/OFF ratio<<1) and large dark-power consumption they are impractical for many large-scale applications (such as pixels in imaging devices). In addition, most of the above-mentioned devices used mechanically exfoliated graphene, which possesses high carrier mobility, and are unsuitable for large-scale deployment. For practical applications high-performance devices using scalable architectures without the need for complex enhancement structures (Muller et al., 2010; Echtermeyer et al., 2011; Liu et al; 2011; Engel et al; 2012; Furhci et al; 2012) are needed. However, no such device has been reported thus far.

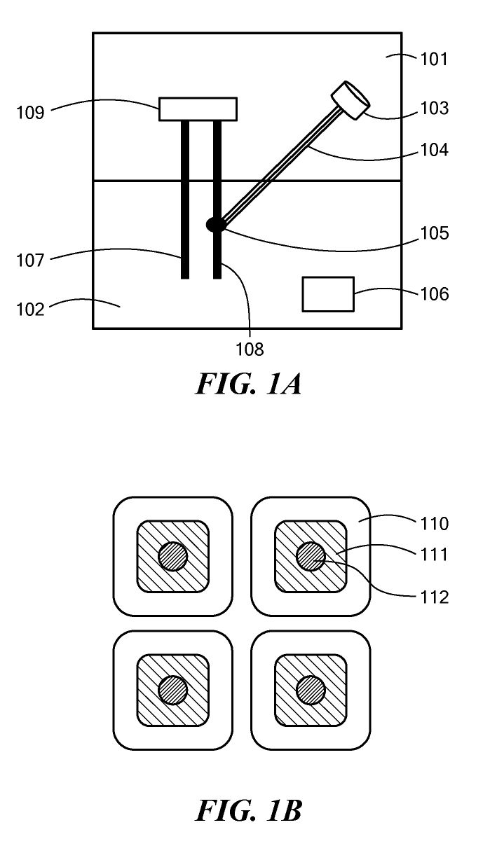

Referring now to FIG. 1A, there is shown a schematic diagram of an exemplary monolithic optoelectronic device having heterojunctions of single-walled carbon nanotubes (SWNT) in the form of belts (107 and 108), and p-doped silicon present in the silicon (Si) layer (102). The SWNT belt is connected through one end to a contact (109) for electrical output. The contact for the electrical output is attached to an insulating layer of SiO₂ (101). An SWNT belt may be illuminated at a spot (105) by a beam of light (104) from a light source (103). A second contact (106) is attached to the Si layer and provides connection for applying a reverse potential.

FIG. 1B is a schematic diagram of a set of four sensors, each having heterojunctions of single-walled carbon nanotubes (SWNT) overlaid on a layer of Si (112). The Si layer is revealed by etching out SiO₂ from a substrate made of a layer of SiO₂ (111) overlaid on a layer of p-doped Si. the SiO₂ layer (111) surrounds the layer of Si. A layer of metallic contact (110) is deposited on the SiO₂ layer and surrounds the portion overlaid with SWNT. Another contact (not shown) attached to the Si layer on the side opposite to that deposited with SWNT provides connection for applying a reverse potential.

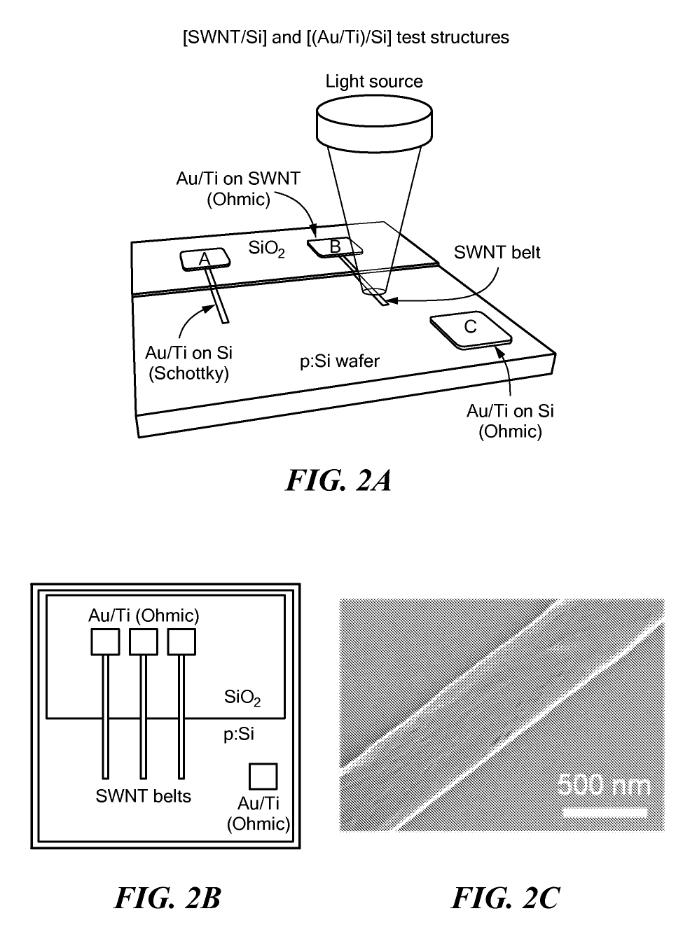

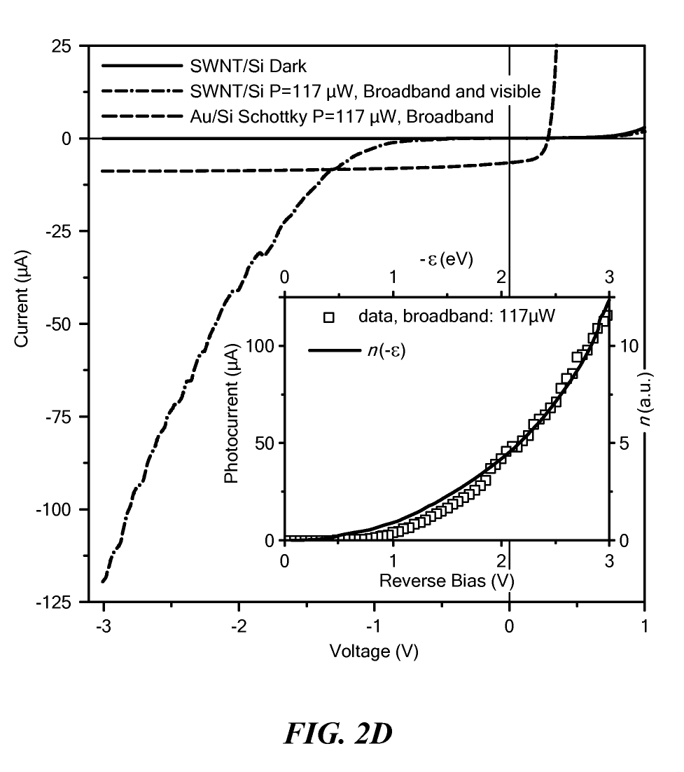

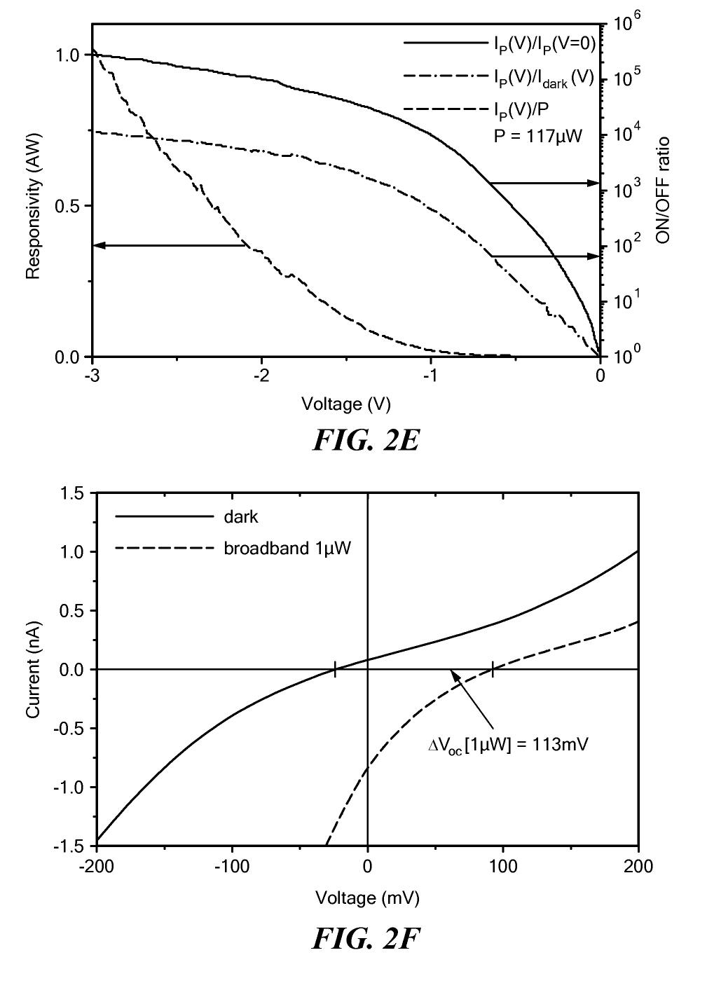

FIG. 2 shows a schematic and a digital photograph of an embodiment of the invention, the embodiment being a typical SWNT-Si test structure. Belts of SWNT (height≈50 nm) with lateral sizes ranging from millimeters (FIG. 2B) to sub-micrometer (FIG. 1C) were assembled in a variety of configurations on lightly p-doped silicon surfaces using a template-assisted fluidic assembly method. (Jaber-Ansari et al., 2008; Xiong, et al., 2007; Kim et al., 2009). Although similar heterojunctions have been described in solar cells (Jia et al., 2008; Jia et al; 2009; Jia et al; 2011; Wadhwa et al., 2011; Li et al., 2009; and Behnam et al; 2008), and photodetectors (Behnam et al. 2008), these devices do not exhibit the extremely high photo-induced ON/OFF ratios at low reverse-bias voltages observed with the devices herein. In past reports, the heterojunctions were modeled in terms of a metal-semiconductor “Schottky-barrier” junction, where the SWNTs are treated as passive, transparent conductive (metallic) electrodes. This simple description is inadequate in explaining the non-linear, reverse-bias dependent photocurrent observed in devices described here, because as described below, the detailed electronic structure and the effective Density of States (DoS) of SWNT belts play a vital role.

Conventional junctions behave according to the diode rectification equation, I(V)□□Iₛ (eqV/nkBT□1), where V is the applied voltage and Iₛ is the reverse saturation current. (Sze et al; 2006). When illuminated, the current follows the photodiode equation, I(V)□□Is (eqV/nkBT□1)□□Iₚₕ, where Iₚₕ is the photocurrent that usually depends on factors such as the incident photon flux and quantum efficiency, but has little or no dependence on the reverse bias. FIG. 2D shows the dark and photo IV (current-voltage) curves in the SWNT-Si junctions fabricated as described in Example 2, along with the photocurrent response in a metal-silicon junction of similar dimensions. Although the dark IV curve in the SWNT-Si junctions shows a conventional rectification behavior, the photocurrent clearly deviates from the conventional behavior, with a near-zero short-circuit current (independent of the incident power) that sharply rises (by several orders of magnitude) within a few volts of reverse bias, Vr. As seen in the same figure, this is strikingly different from the photo IV curve of a conventional metal/Si Schottky junction of comparable dimensions, illuminated with the same light source.

A semi-quantitative model that includes ab-initio density functional theory calculations of the band structure of these heterojunctions was developed, and is described below. The model revealed that the sharply non-linear photocurrent behaviour is closely related to the reverse-bias tuneable total available states in the SWNT belts, n(ε=eVr) for the photoexcited carriers to inject into the SWNT belts, from silicon.

Notably, electron affinity of Si is χSi≈4.05 eV, whereas the work-function of SWNT mats is, χSWNT≈3.7-4.4 eV (Groning et al., 2000; Ruffieux et al., 2002). Therefore, in an unbiased junction, the Fermi level of SWNT lie very close to the conduction band edge (CBE) of Si. Since SWNT have low DoS near their Fermi level any photoexcited electrons near the CBE find very few accessible states in SWNTs to inject into, resulting in the near-zero short-circuit photocurrent seen in the devices described here (Example 3). Under an applied reverse bias, however, the Fermi level of SWNT becomes lowered, allowing regions of high DoS (and hence, a large number of unoccupied accessible states) to align with the CBE of Si. Therefore, a large number of photoexcited carriers can inject into SWNTs. The photocurrent is hence limited by the number of accessible states between the position of the CBE of Si and the Fermi level of SWNT (at ε=eVᵣ, where Vᵣ is the reverse bias), and its voltage dependence can also be expected to follow the electron-energy dependence of the number of accessible states, n(ε=eVr), obtained by integrating the SWNT DoS between ε=0 and ε=eVr.

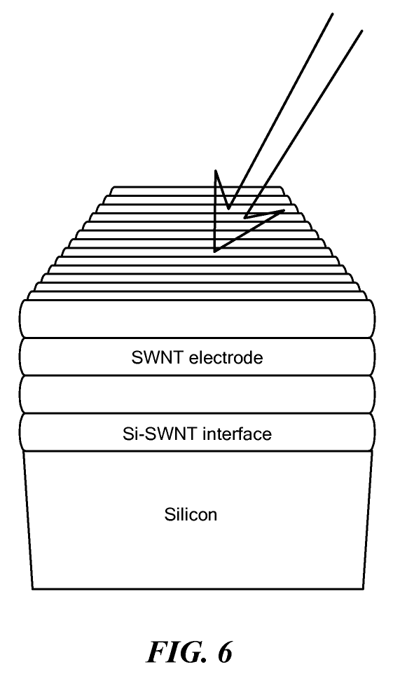

Therefore, in the first approximation, it is assumed that the voltage dependence of the measured photocurrent is directly proportional (ignoring the geometry of the electrodes) to the total number of accessible states n(ε) for the photoexcited carriers from Si to inject into SWNT. To obtain n(ε), it is further assumed that the heterojunction can be divided into three regions, namely the (a) the bulk Si region, (b) the Si-SWNT interface, and (c) the SWNT electrode, as shown in FIG. 6. Ab-initio DFT calculations were performed to obtain the electronic structure of the SWNT-Si interface, and data available from published results were used to model the electronic structure of (c). The non-linear and voltage-dependent photocurrent was modeled using a combination of these results as shown below. The model produced a reasonable agreement between the electron energy (voltage) dependence of (a) the number of accessible states and (b) the photocurrent.

Ab-Initio DFT Modeling of SWNT-Si Interface:

First-principle DFT calculations were performed using SIESTA code (Soler et al. 2002) to investigate the geometrical and electronic structures of (6,2) CNT on p4×4-Si(100) surface. The generalized gradient approximation (GGA; Perdew et al., 1986) functional by Perdew, Burke, and Ernzerhof (PBE; Perdew, et al., 1996) for exchange-correlation functional, and Troullier-Martins type norm-conserving pseudopotentials were used for the calculations. (Troullier et al., 1991). An atomic orbital basis with a double-ζ polarization was used to expand the electronic wave functions. A 200 Ryd mesh cutoff was chosen and the self-consistent calculations were performed with a mixing rate of 0.05. The convergence criterion for the density matrix was taken as 10⁻⁴. The conjugate gradient method (Hestenes et al., 1952) was used to relax the atoms until the maximum absolute force was less than 0.05 (eV/Å). A p(4×2) reconstruction of the Si(100) surface was used for substrate structure of semiconducting SWNTs. A slab with 7 silicon monolayers was used, and the bottommost layer was hydrogen (H) terminated. Except the bottom 2 Si layers, all the atoms were fully relaxed with several types of buckled Si structures at the surfaces. The most stable p(4×2) Si(100) surface structures were found and their electronic band structure were calculated with k-grid 12×24×1. The lattice constant of Si(100) slab along x-axis (longer, p4×2) was 15.3685 Å, and the band gap was 0.416 eV. By comparing with the band structure of Si(100) bulk and surface structure, it was confirmed that the band dispersion near the Fermi level of Si(100) surface was due to the surface structure which resulted in reduced band gap from ˜1.1 eV to 0.416 eV. The vacuum region in the vertical direction (z-axis) was at least 10 Å with adsorption of SWNTs on the Si(100) surface to ignore the interaction between periodic images. We also considered the slab dipole-correction to introduce a dipole layer in the vacuum region to compensate the system dipole.

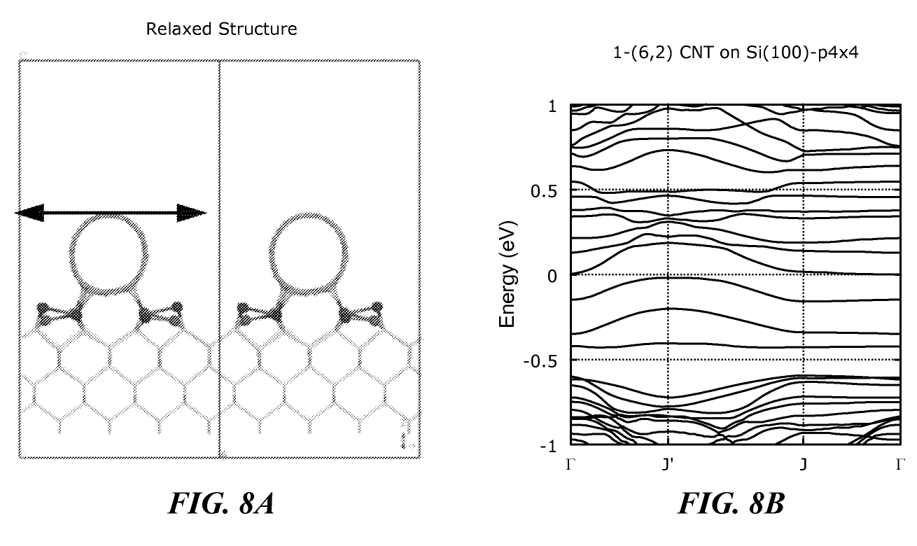

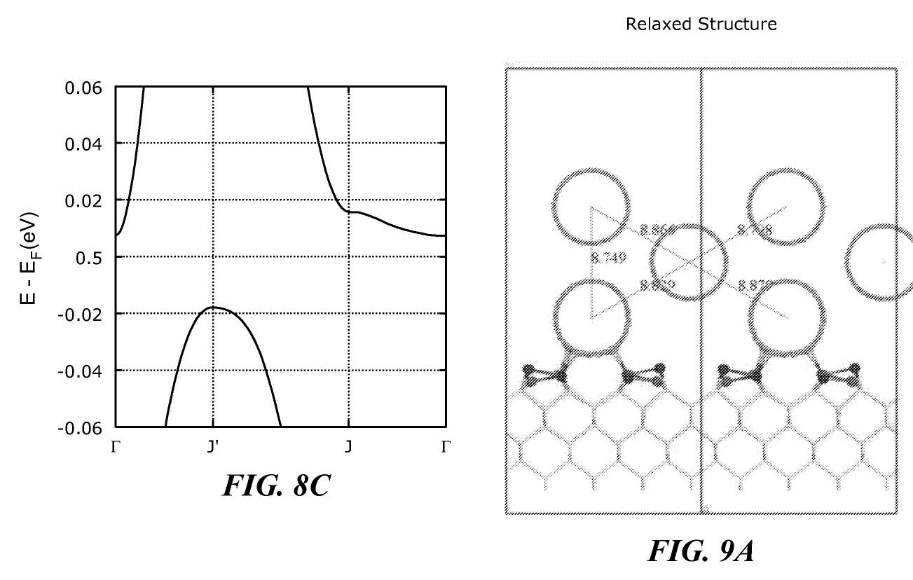

Next this SWNT was adsorbed on the surface of 100-surface of Si, and structure relaxation was performed for 1 SWNT per supercell and the band-structure calculated using a periodic boundary condition. FIG. 8 summarizes the result of these calculations. The optimized structure was determined to have a reduced band gap of about 0.025 eV.

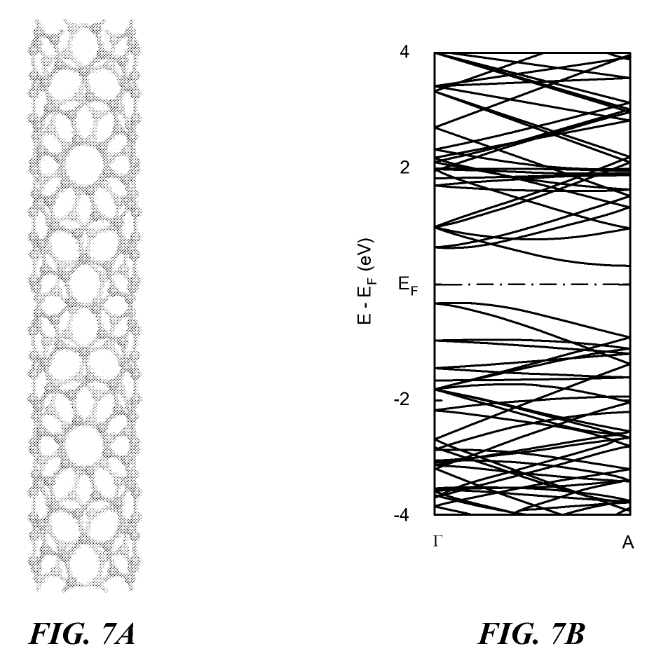

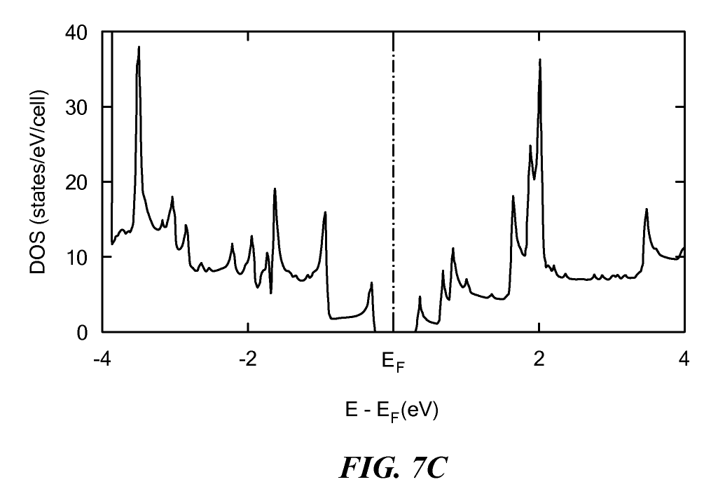

A suitable SWNT with chirality (6,2), which has a similar lattice constant (along the tube axis) to that of the Si(100)-p4×2 structure (ALAT: 15.369 Å) was selected. FIG. 7 shows the calculated electronic band structure and Density of States (DoS) of the isolated (6,2) SWNT.

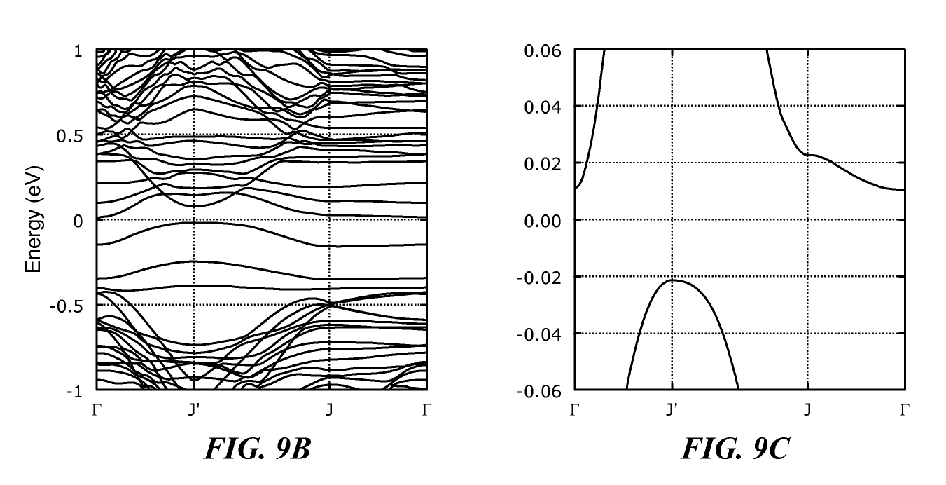

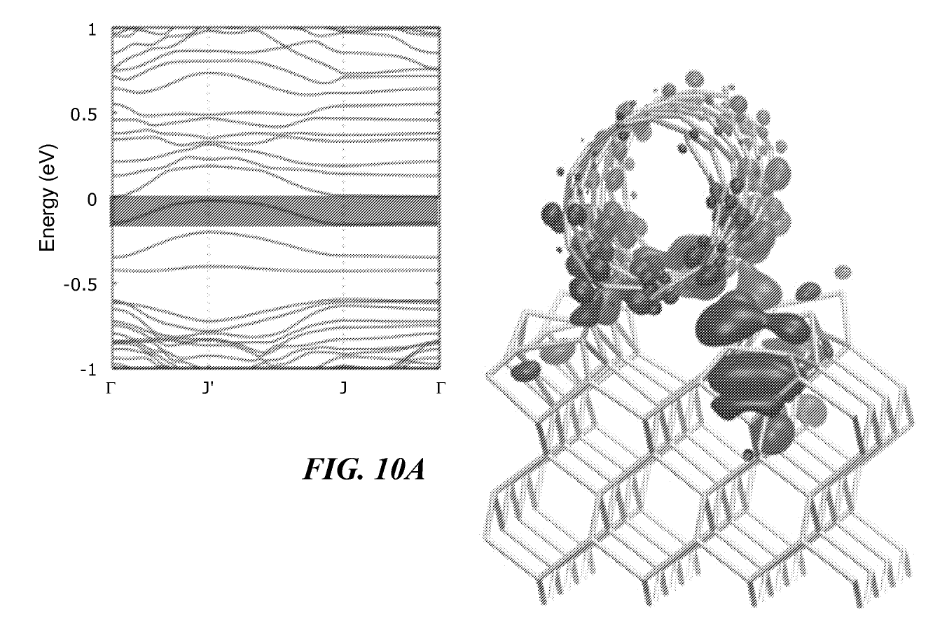

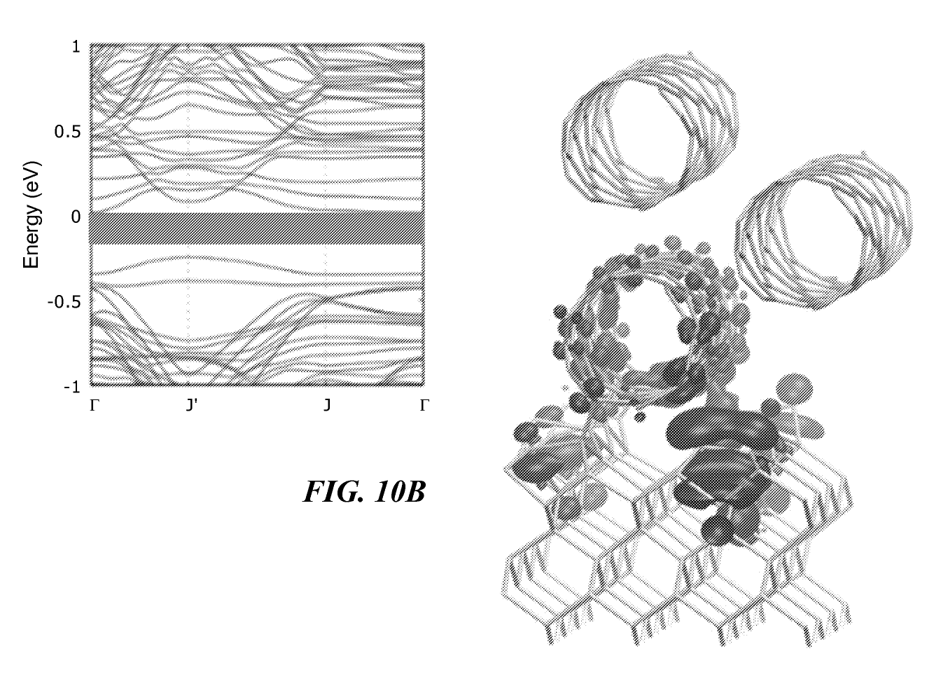

To obtain a more realistic picture of a continuous layer at the intersection, the number of nanotubes per supercell was increased to three. FIG. 9 shows the relaxed structure and band structure of the 3-(6,2) CNT on Si. A small increase in band-gap was observed.

Semi Quantitative Modeling of the SWNT Electrodes:

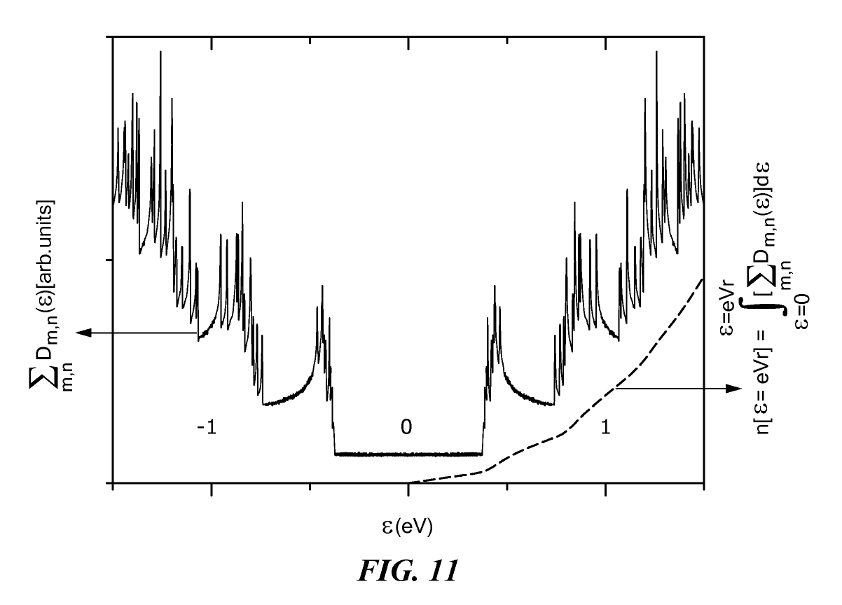

A simple model was employed to describe the effective electronic structure of the SWNT belts as electrodes (layer c of FIG. 6; left). Since the as-received SWNTs had d≈1 nm, it was assumed that the belts contain an equal distribution of all chiralities (m,n) with d≈1 nm. The cumulative DoS (CDoS) of the SWNT belts was assumed to be proportional to an equally weighted sum of the individual DoS (Saito et al., 2000) of each chiral type, CDoS=Σm,nDm,n(ε). Here, ε=0 eV is the Fermi level, assumed to be the same for all SWNTs for the sake of simplicity. FIG. 11 shows the cumulative DoS (CDoS) of SWNTs (obtained by summing the DoS of 22 different chirality values of SWNTs with d≈1 nm as shown), as a function of electronic energy, ε. Also shown is the number of accessible states above the Fermi level.

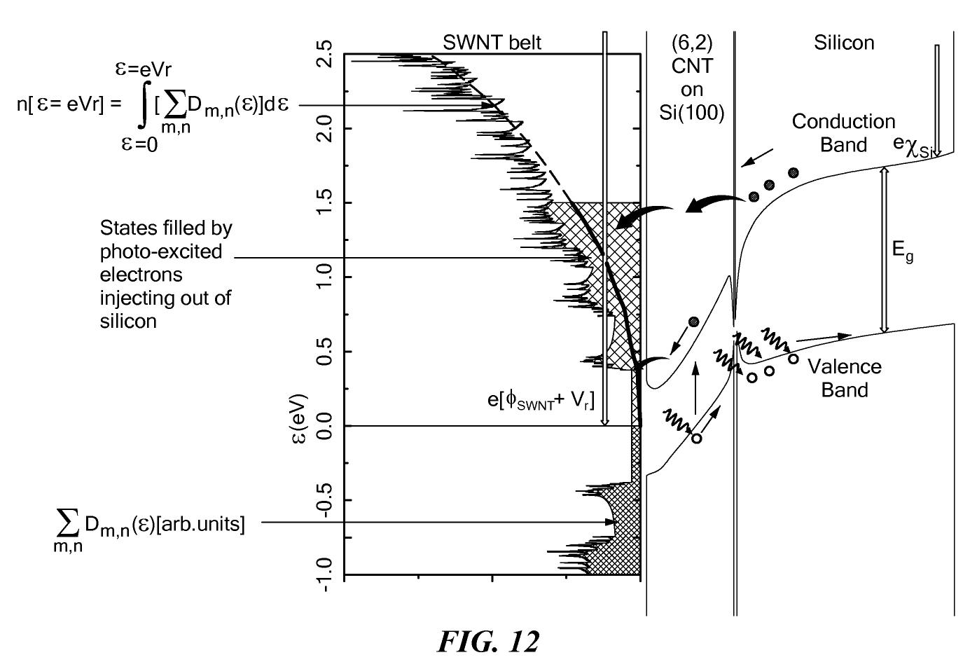

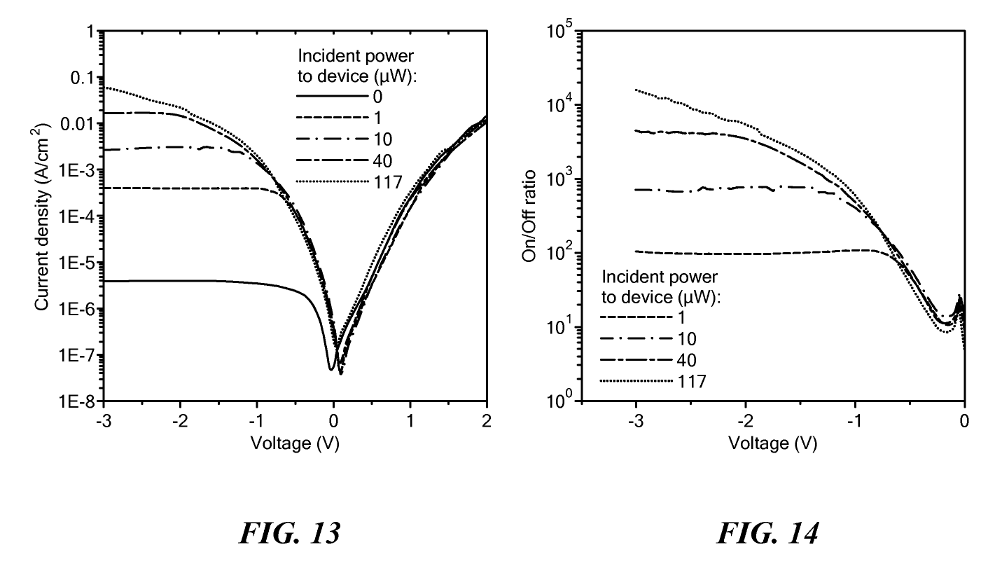

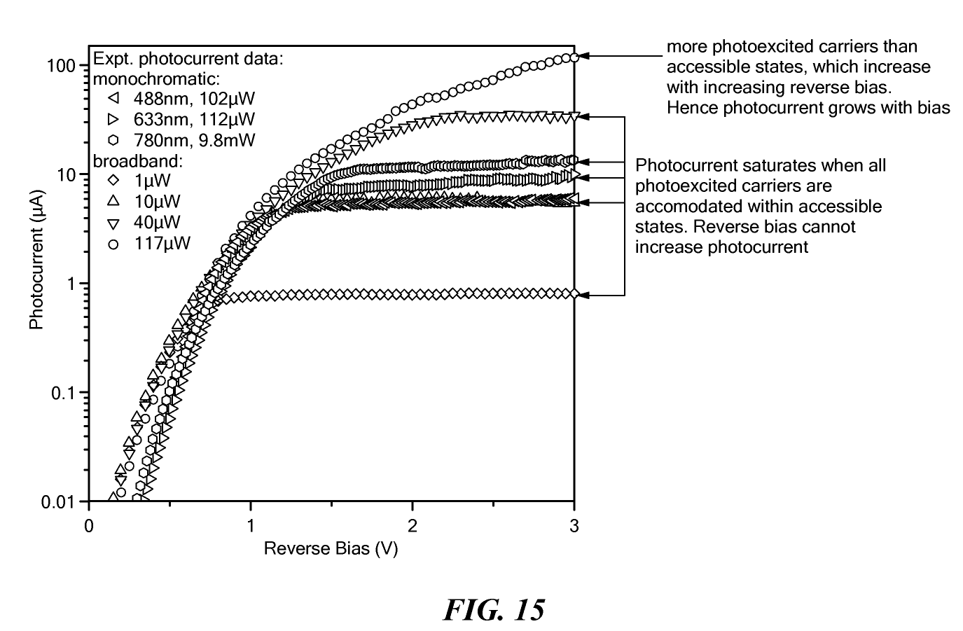

It is further proposed that the intermediate layer (layer b) is narrow, and hence the carrier injection through this layer is not going to be significantly affected by the actual layer of SWNT that form this interface, and hence we can choose the (6,2) SWNT as a typical SWNT sandwiched between the electrode and silicon. The combined electronic structure of the SWNT electrode, a (6,2) SWNT, and its junction with Si under the application of a reverse bias is shown in FIG. 12. The band gaps at various regions have been schematically represented from the values discussed above. The semiconducting (6,2) SWNT forms an ultrathin, nearly-metallic junction through which photoexcited carriers can easily penetrate, travel through a very short distance (possibly a few nanotube's width) before it arrives at the SWNT electrode area. The schematic also shows how the CDoS of the SWNT electrode shifts towards lower energy values due to an applied reverse bias Vr. The Fermi level of SWNTs gets lowered by an amount equal to the reverse bias Vr, with respect to its original position near the CBE of Si. As a result, under this applied reverse bias, the Fermi level, and hence the number of electron-occupied states of the SWNT belt move to lower energies, opening up accessible states for photoexcited electrons to inject from Si into the SWNT. From the CDoS, the total number of accessible states, n(Vr), is calculated using the formula shown in FIG. 12.

The variation of n=n(eVᵣ) as a function of Vᵣ has been plotted in FIGS. 11 and 12 as well as in FIG. 2D inset for comparison with the measured photocurrent. It can be seen that despite the simple approach of this model, the shape of n=n(eVr) is quite consistent with that of experimental photocurrent data obtained and described here, suggesting that the SWNT DoS plays a key role in determining the photocurrent response in these devices. A more accurate description of the CDoS, incorporating the atomistic interaction (Kwon et al., 1998) between SWNT/Si and SWNT/SWNT junctions (sidewall and end-end) is possible and may result in more quantitative description of the behavior of these junctions.

Turning now to the inset of FIG. 2D, a comparison of Iₚₕ and n(ε) as a function of Vᵣ and ε, respectively, is shown and a close correlation between two is observed. FIG. 2E shows the variation of photocurrent responsivity R=Iₚₕ/P, the electrical ON/OFF ratio I_{P}(V)/I_{P}(V=0) and optical ON/OFF ratio=I_{P}/I_{dark} of the SWNT/Si junction at voltage V. The maximum responsivity Rₘₐₓ obtained in the devices at a low reverse bias (−3V) exceeds 1 A/W, making the devices highly attractive both as photo-detectors as well as on-chip switching devices. Moreover, the response is completely tuneable between 0<R<Rₘₐₓ using very low voltages (−3V-0V), which is extremely useful for brightness adjustable imaging in variable-light conditions, making the devices also attractive for imaging technologies. Further, the low dark current and the incident power-independent low short-circuit currents coupled with this high responsivity at V=−3V results in high electrical ON/OFF ratio exceeding 2.5×10⁵, and optical ON/OFF ratios exceeding 10⁴. Such high current-switching ratios are difficult to obtain in mixed-chirality SWNT arrays using purely electric field effects (gate-voltage). (Seidel et al. 2004). FIG. 2F shows the dark, and P=1 μW IV curves in the SWNT/Si device. Under 1 μW incidence, the open-circuit voltage shifts by an amount ΔV_{∝}=113 mV, which corresponds to a significantly large voltage responsivity of R_{V}>10⁵ V/W, and is orders of magnitude higher than past reports (Wen et al., 2010; Wang et al; 2010; Vasil'ev et al., 2009), making it attractive for designing low-power/portable weak-signal detecting, imaging, and on-chip analytical photochemistry applications.

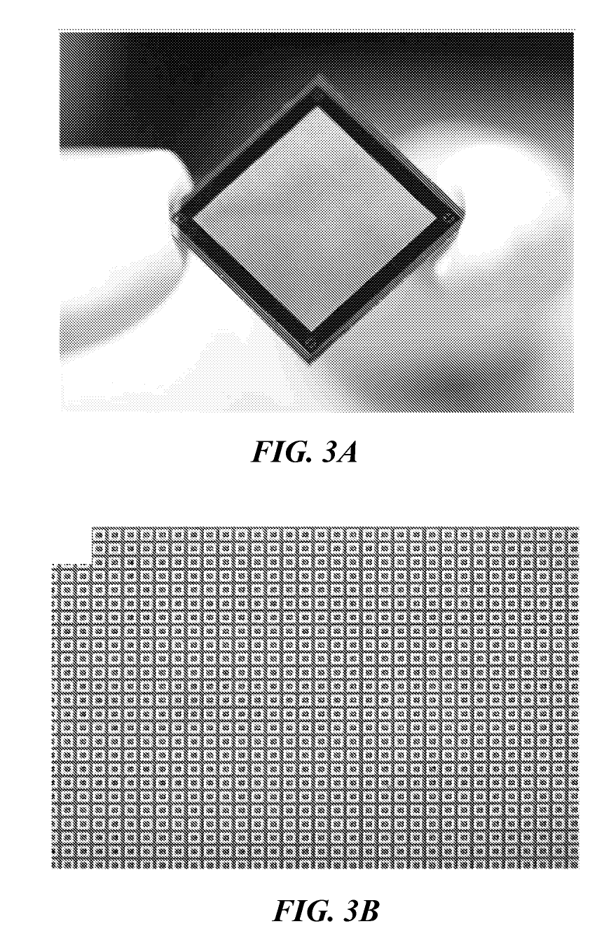

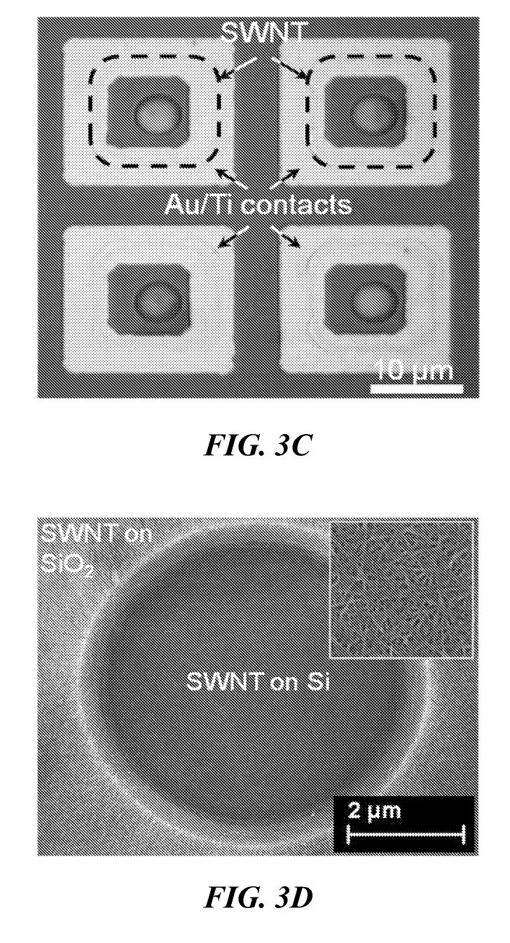

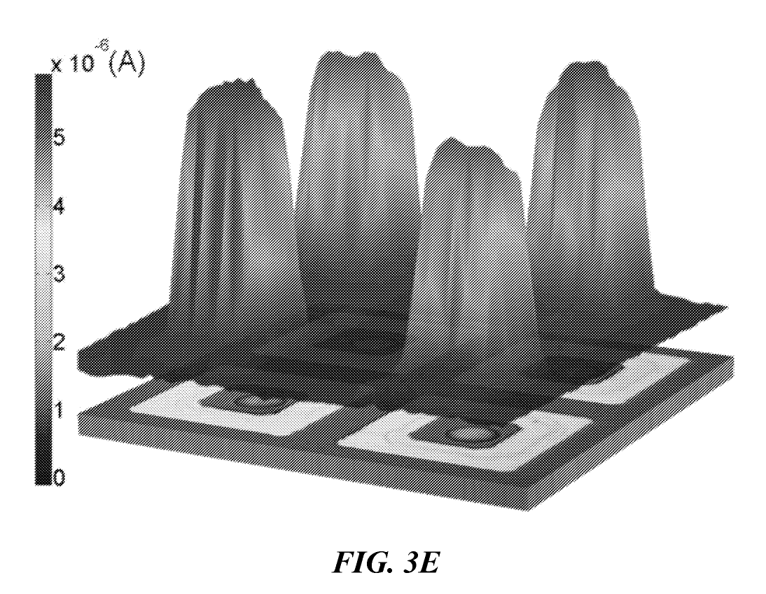

FIG. 3 summarizes the potential application of the tuneable photo-response described above in imaging technologies. The robust structural scalability and functional reproducibility of the fluidic assembly method is demonstrated by fabricating an array of 250,000 junctions on a 12×12 mm² area SiO₂/Si chip, designed to mimic the front-end of a 0.25 Megapixel focal plane array. Each sensor contains an isolated 15×15 μm² fluidically-assembled SWNT film conformally overlaid onto a 5-μm-diameter Si window etched out of a 300-nm thick SiO₂ layer. FIG. 3 A-C shows digital photographs of one such sensor array at different magnification levels, highlighting the fault-free large-scale integration achievable using our technique. The dense, uniform coverage of the circular Si window without any stray suspended SWNT or bubbles as seen in FIG. 3D is typical for all areas across the chip, and no structurally defective “sensor” was found under random SEM inspection of hundreds of sensors over the entire chip. This level of structural reproducibility is important for large-area integration of sensors. FIG. 3E shows a typical scanning photocurrent map of four pixels in a specially prepared chip where the front electrodes were lithographically shorted to a common external contact pad. The photocurrent maps show uniform photo-response from all the pixels, without any cross-talk evident.

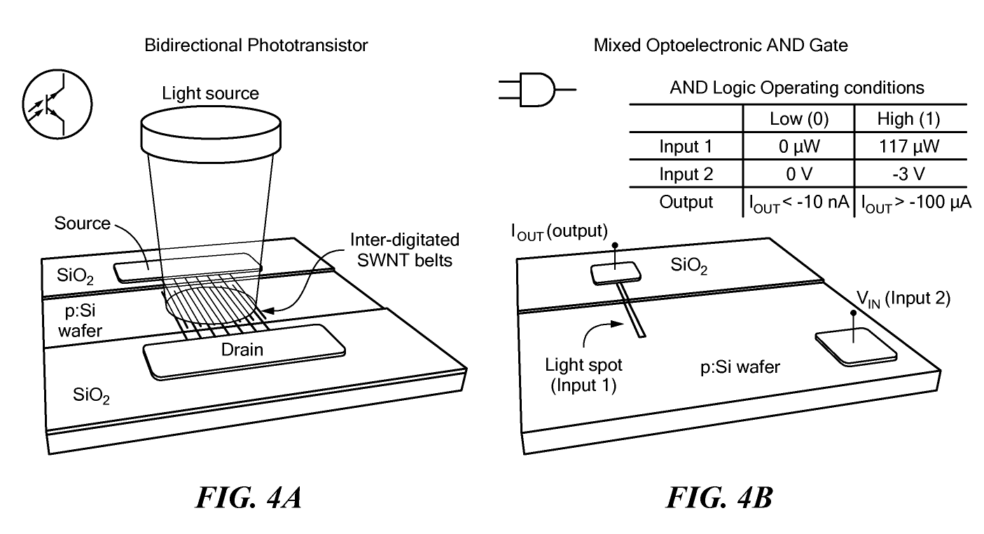

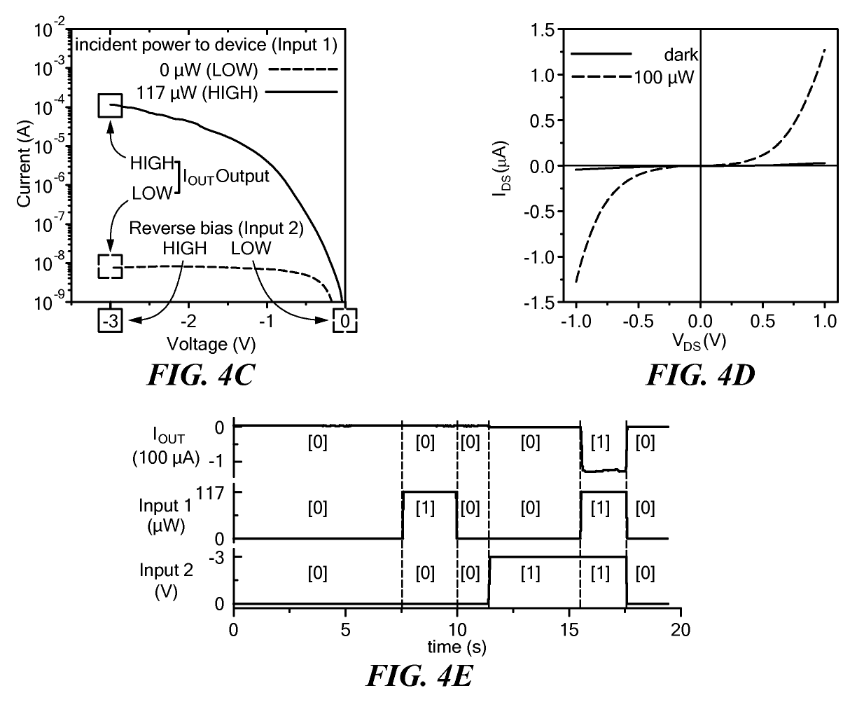

In various embodiments of the invention the heterojunction above is used as monolithic hybrid optical/electronic logic elements for different analog and digital applications. FIG. 4A shows “interdigitated” SWNT belts connected to source and drain electrodes, equivalent to two “back-to-back” photodiodes which form a bidirectional phototransistor, as seen from the dark and photo-IV curves in FIG. 4D. In darkness, the device remains switched OFF for applied voltages of either polarity, while under illumination, an ON state can be obtained for both positive and negative voltages. In this configuration, the device is an optoelectronic equivalent of a symmetric FET (field effect transistor), where the gate voltage has been replaced by photons. Further, the applied voltage and incident light form two independent methods for controlling the channel current, both of which must be present to obtain an ON state. This feature allows one to construct a mixed-input optoelectronic AND gate, as described in FIG. 4B. Here, the light spot incident on the SWNT-Si junction (input 1 measured in μW) and the applied bias (V_{IN}) are the two logic inputs, while the measured current output I_{OUT} is the logic output. The optical and electrical ON and OFF states for a typical device can be obtained for the dark and photo-IV curves, as shown in FIG. 4C. For convenience, the states have been tabulated in FIG. 4B. A typical time-trace of the output state I_{OUT}, for different logic states of inputs 1 and 2 is shown in FIG. 4E confirming its operation as a mixed optoelectronic AND gate.

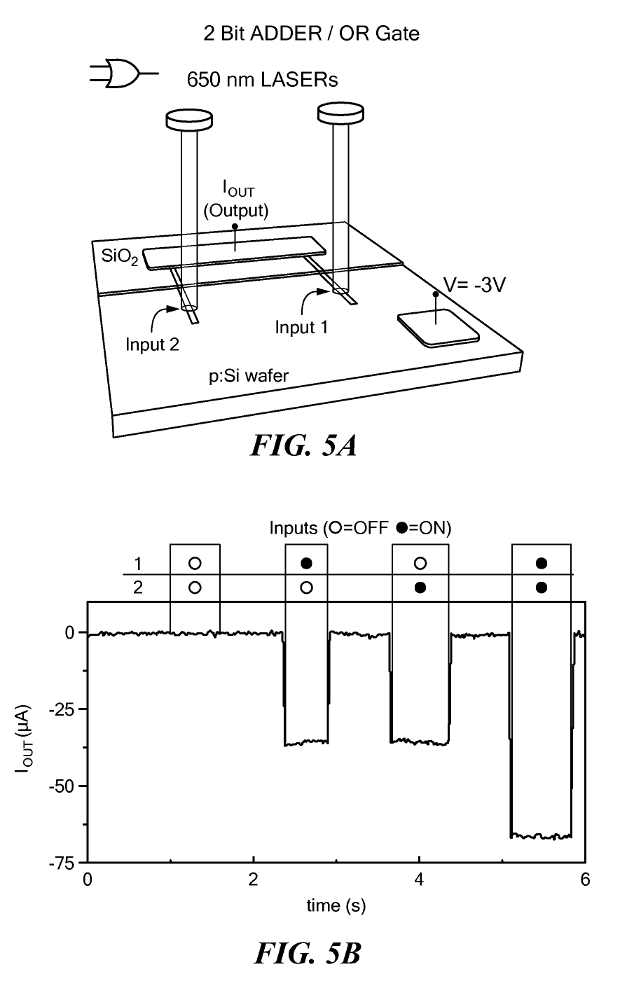

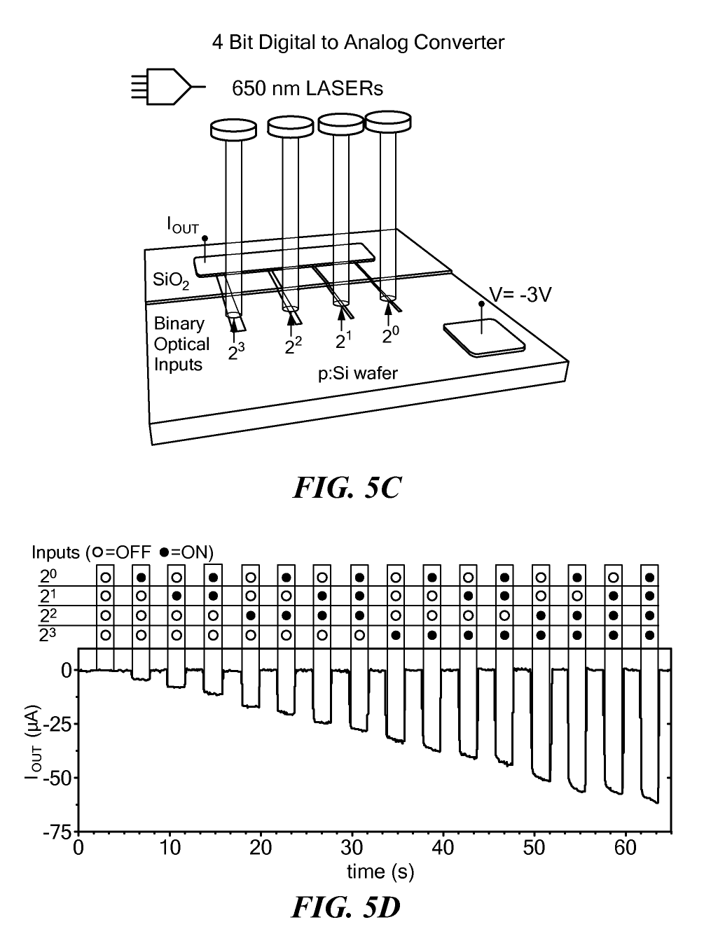

The responsivity in different junctions fabricated in the same batch was found to be highly reproducible indicating that the “optical input-electronic output” devices were found to be capable of operating with multiple optical inputs. FIG. 5A shows a 2-Bit, digital-optical-input, voltage-switchable analog-output ADDER circuit, where the device adds two digital optical input signals and provides an output which is an analog equivalent of the digital sum. The calculation is performed only when a reverse bias is applied, which can be used as a clock-trigger for this calculation. Under appropriate logic conditions, the device also serves as an OR gate, and these operations can be seen in the output time-trace for different input states in FIG. 5B The high-fidelity adding operation can be extended to design more complex input bits by lithographically designing junctions with highly controlled surface areas. FIG. 5C demonstrates a voltage-switchable 4-Bit optoelectronic Digital to Analog converter. To achieve this conversion, four separate SWNT/Si junctions, with their junction area proportional to 2⁰,2¹,2², and 2³ were designed (by fabricating 1, 2, 4, and 8 parallel identical SWNT belts, respectively) to mimic the significant bits of a 4-Bit optical input, each of which could be independently illuminated (or kept dark), resulting in binary inputs, 0000-1111. The corresponding electrical output, when triggered by a reverse bias, is the analog equivalent of these inputs. (FIG. 5D). The Figure shows that there is a high degree of correspondence between the binary inputs and the electrical output.

The SWNT-silicon junctions described here form a versatile platform for a variety of optoelectronic applications ranging from photo-detection, photometry, and imaging. Moreover, the voltage switchable photocurrent with high switching ratio allows one to conceive mixed optoelectronic logic elements, voltage-triggered digital optoelectronic operations, and digital-to-analog conversions. The room temperature and wafer-level scaling compatibility of the template-guided fluidic assembly technique provides enormous robustness and reproducibility of these devices over large areas. The on-chip architectures are completely compatible with conventional microelectronics technologies, including possible inclusion of waveguides and other photonic components.

### EXAMPLES

### Example 1

### Materials

Single-wall carbon nanotubes of mixed chirality were commercially purchased and assembled using a template-assisted fluidic assembly (Example 2) as needed on Si and SiO₂ surfaces. Ti/Au contacts were attached using standard lithographic techniques. The 0.25. MegaPixel detector array prototype (Example 4) was fabricated using a combination of lithographic and fluidic assembly steps. Photocurrent measurements were performed using a Keithley 2400 sourcemeter and a range of calibrated broadband and monochromatic light sources was used as optical inputs.

### Example 2

### Fabrication of Heterojunctions by Fluidic Assembly and Lithography

As a general procedure a p-doped Si layer covered with an insulating layer was used as the substrate in the preparation of heterojunctions. The insulating layer used was a layer of SiO₂. The insulated layer was removed from selected regions using lithography, thereby revealing the p-doped Si layer. Next, the surface of the substrate was etched with plasma to render the surface hydrophilic. A hydrophobic mask layer over was deposited over the entire surface. The hydrophobic mask layer was patterned to produce one or more microscale or nanoscale trenches or patches as needed. The substrate was then submerged in a suspension of SWNT. Next, the substrate was withdrawn up through the SWNT suspension, resulting in selective deposition of SWNT in the trenches or patches to form one or more heterojunctions between the deposited SWNT and the p-doped Si. If needed, the hydrophobic mask layer was removed. Two electrical contacts were deposited, one on the insulating layer contacting the deposited SWNTs to serve as a connection for electrical output, and another on the p-doped silicon layer for connecting to the source of a reverse potential. In the case of the bidirectional phototransistor (FIG. 4A), both electrical contacts were deposited on the insulating layer.

### Example 3

### Optoelectronic SWNT-Si Device

Belts of SWNT (height≈50 nm) with lateral sizes ranging from millimeters to sub-micrometer (FIG. 2B) were assembled in a variety of configurations on lightly p-doped silicon surfaces using a template-assisted fluidic assembly method. (Jaber-Ansari et al., 2008; Xiong, et al., 2007; Kim et al., 2009). Similar heterojunctions have in past reports been modeled in terms of a metal-semiconductor “Schottky-barrier” junction, where the SWNTs are treated as passive, transparent conductive (metallic) electrodes. This simple description is inadequate in explaining the non-linear, reverse-bias dependent photocurrent seen in the devices described herein. The detailed electronic structure and the effective DoS of SWNT belts play a vital role.

Conventional junctions are expected to follow a diode rectification equation (Sze et al. 2006). When illuminated, the current follows a photodiode equation, where the photocurrent that usually depends on factors such as the incident photon flux and quantum efficiency, but has little or no dependence on the reverse bias. The dark and photo-IV curves in the SWNT-Si junctions, along with the photocurrent response in a metal-silicon junction of similar dimensions as a control (FIG. 2D). Although the dark IV in the SWNT-Si junctions was observed to follow a conventional rectification behavior, the photocurrent clearly showed deviation from the conventional behavior, with a near-zero short-circuit current (independent of the incident power, that rises sharply (by several orders of magnitude) within a few volts of reverse bias, Vᵣ. This behavior is strikingly different from the photo-IV of a conventional metal/Si Schottky junction of comparable dimensions, illuminated with the same light source. (FIG. 2D).

A semi-quantitative model that includes extensive ab-initio density functional theory calculations (see detailed description) of the band structure of these heterojunctions revealed that the sharply non-linear photocurrent behavior is closely related to the reverse-bias tuneable total available states in the SWNT belts, n(ε=eVr) for the photoexcited carriers to inject into the SWNT belts from silicon. A comparison of Iₚₕ and n(ε) as a function of V, and e, respectively shows a close correlation between the two. (FIG. 2D inset).

The variation of photocurrent responsivity R=Iₚₕ/P, the electrical ON/OFF ratio IP(V)/IP(V=0) and optical ON/OFF ratio=Iₚₕ/I_{dark} of the SWNT/Si junction at voltage V is shown in FIG. 1E. In the devices described here the maximum responsivity Rₘₐₓ obtained at a low reverse bias (−3V) was observed to exceed 1 A/W, making the devices highly attractive both as photo-detectors as well as on-chip switching devices.

Further, the response was observed to be completely tuneable between 0<R<Rₘₐₓ using very low voltages (−3V-0V). This property is extremely useful for brightness adjustable imaging in variable-light conditions in developing imaging technologies.

The low dark current and the incident power-independent low short-circuit currents coupled with high photocurrent high at V=−3V resulted in a high electrical ON/OFF ratio exceeding 2.5×10⁵, and optical ON/OFF ratios exceeding 10⁴. Such high current-switching ratios are difficult to obtain in mixed-chirality SWNT arrays using purely electric field effects (gate-voltage). (Seidel et al. 2004).

IV curves obtained at dark and at P=1 μW using SWNT/Si device described herein are shown in FIG. 2E. Under 1 μW incidence, the open-circuit voltage shifts by an amount ΔV_{∝}=113 mV, which corresponds to a significantly large voltage responsivity of RV>10⁵ V/W, and is orders of magnitude higher than past reports (Wen et al., 2010; Wang et al., 2010; Vasil'ev et al. 2009). The observed high voltage responsivity makes the devices appealing for designing low-power/portable weak-signal detecting, imaging, and on-chip analytical photochemistry applications. (Wen et al., 2010; Wang et al., 2010 Vasil'ev et al. 2009).

### Example 4

### Optoelectronic SWNT-Si Array

FIG. 3 summarizes the potential application of this tuneable photo-response in imaging technologies. The robust structural scalability and functional reproducibility of the fluidic assembly method is demonstrated by fabricating an array of 250,000 junctions on a 12×12 mm² area SiO₂/Si chip to mimic the front-end of a 0.25 Megapixel focal plane array. Each sensor contains an isolated 15×15 μm² fluidically-assembled SWNT film conformally overlaid onto a 5-μm-diameter Si window etched out of a 300-nm thick SiO₂ layer. FIG. 3A-C show digital photographs of one such sensor array at different magnification levels, highlighting the fault-free large-scale integration achievable using methods described herein (Example 2). The Si window is uniformly and densely covered with SWNTs and no stray suspended SWNTs or bubbles were observed. (FIG. 3D). Such coverage was typical for all areas across the chip. Random SEM inspection of hundreds of sensors over the entire chip showed no structurally defective “sensor”.

Scanning photocurrent maps were obtained for a specially prepared chip having four sensors (pixels) in which the front electrodes were lithographically shorted to a common external contact pad. The photocurrent maps obtained typically showed uniform photo-response from all the pixels and the absence of any cross-talk between pixels. (FIG. 3E)

### Example 5

### SWNT-Si Bidirectional Phototransistor

The monolithic hybrid optical/electronic logic elements (Example 3) were used to construct a bidirectional phototransistor FIG. 4A. Belts of SWNT were interdigitated with Si, and the belts were further connected to source and drain electrodes such that one set of the SWNT belts was connected to a source contact, and another set of SWNT belts was connected to a drain contact as indicated. The design is equivalent to two “back-to-back” photodiodes which form a bidirectional phototransistor, as seen from the dark and photo-IV curves shown in FIG. 4D. In darkness, the device remained switched OFF for applied voltages of either polarity, while under illumination an ON state was obtained for both positive and negative voltages. In this configuration, the device is an optoelectronic equivalent of a symmetric FET, where the gate voltage has been replaced by photons.

Further, the applied voltage and incident light form two independent methods for controlling the channel current, both of which must be present to obtain an ON state. This feature allows one to construct a mixed-input optoelectronic AND gate, as shown in FIG. 4B. The light spot incident on the SWNT-Si junction (input 1 measured in μW) and the applied bias (V_{IN}) are the two logic inputs, and the measured current output I_{OUT} is the logic output. The optical and electrical ON and OFF states for a typical device was obtained for the dark and photo-IV curves as shown in FIG. 4C, and for convenience, has been tabulated in FIG. 4B. Further, FIG. 4E shows a typical time-trace of the output state I_{OUT}, for different logic states of inputs 1 and 2, confirming the operation of the device as a mixed optoelectronic AND gate.

### Example 6

### Monolithic Optoelectronic Devices with SWNT-Si Heterojunctions and Multiple Optical Inputs

A 2-Bit, digital-optical-input, voltage-switchable analog-output ADDER circuit was constructed. (FIG. 5A) The device adds two digital optical input signals and provides an output which is an analog equivalent of the digital sum. The addition is performed only when a reverse bias is applied, which can be used as a clock-trigger for this calculation. Under appropriate logic conditions, this also serves as an OR gate, and these operations can be seen in the output time-trace for different input states in FIG. 5B. The high-fidelity adding operation can be extended to design more complex input bits by lithographically designing junctions with highly controlled surface areas, which is demonstrated by the construction of a voltage-switchable 4-Bit optoelectronic Digital to Analog converter. (FIG. 5C). For constructing the converter four separate SWNT/Si junctions, with their junction area proportional to 2⁰,2¹,2², and 2³ were designed (by fabricating 1, 2, 4, and 8 parallel identical SWNT belts, respectively) to mimic the significant bits of a 4-Bit optical input, each of which could be independently illuminated (or kept dark), resulting in binary inputs, 0000-1111. The corresponding output, when triggered by a reverse bias is the analog equivalent of these inputs. (FIG. 5D). The analog reproduction was found to be very close match of the binary inputs.

### REFERENCES

Almeida, V. R., Barrios, C. A., Panepucci, R. R. & Lipson, M. All-optical control of light on a silicon chip. Nature 431, 1081-1084 (2004)
Bertrand, G., Deleonibus, S., Previtali, B., Guegan, G., Jehl, X., Sanquer, M. & Balestra, F. Towards the limits of conventional MOSFETs: case of sub 30 nm NMOS devices. Solid-State Electronics 48, 505-509 (2004)
Behnam, A., Johnson, J. L., Choi, Y., Ertosun, M. G., Okyay, A. K., Kapur, P., Saraswat, K. C. & Ural, A. Experimental characterization of single-walled carbon nanotube film-Si Schottky contacts using metal-semiconductor-metal structures. Applied Physics Letters 92, 243116-243116-243113 (2008)
Bogaerts, W., Selvaraja, S. K., Dumon, P., Brouckaert, J., De Vos, K., Van Thourhout, D. & Baets, R. Silicon-on-insulator spectral filters fabricated with CMOS technology. Selected Topics in Quantum Electronics, IEEE Journal of 16, 33-44 (2010)
CMOS-compatible Optical Interconnects and I/O, Section 5.3, page 58, International Technology Roadmap for Semiconductors, 2011 Edition, Interconnect, www.itrs.net/Links/2011ITRS/2011Chapters/2011Interconnect.pdf
Echtermeyer, T. J.; Britnelt, L.; '..lasnos, P. K.; Lombardo, A.; Gorbachev, R. V.; Grigorenko, A. N.; Celt>>, A, K; Ferrari, A. C.; Novoselov, K. S.; Strong Plasmonic enhancement of pholovollage in graphene. Nature Communications. 2, 458, (2011)
Engel, M.; Steiner, M.; Lombardo, A.; Ferrari, A. C., Lohneysen, H. v.; Avouris, P.; Krupke, R.; Light-matter interaction in a microcavity-controlled graphene transistor Nature Communications 3, 906 (2012)
Furchi, M.; Urich, A; Pospischil, A.; Lilley, G.; Unterrainer, K.; Detz, H.; Kiang, P.; Andrews, A, M.; Schrenk, W.; Strasser, G.; Mueller, T.; Microcavity-Integrated Graphene Photodetector, Nano Lett. 12, 2773-2777 (2012)
Gabor, N. M., Song, J. C. W.; Ma, Q.; Nair, N, L.; Taychatanapat, T.; Watanabe, K.; Taniguchi, T.; Levilov, L. S.; Jarillo-Herrero, P.; Hot carrier-assisted intrinsic photoresponse in graphene, Science 334, 648-652 (2011)
Groning, O., Kuttel, O., Emmenegger, C., Groning, P. & Schlapbach, L. Field emission properties of carbon nanotubes. Journal of Vacuum Science & Technology B: Microelectronics and Nanometer Structures 18, 665-678 (2000)
Hestenes, M. R. & Stiefel, E. Methods of conjugate gradients for solving linear systems. Journal of Research of the National Bureau of Standards, 49, 409-432 (1952)
Hofmann, W. H., Moser, P. & Bimberg, D. Energy-Efficient VCSELs for Interconnects. Photonics Journal, IEEE 4, 652-656 (2012)
Hofstein, S. & Heiman, F. The silicon insulated-gate field-effect transistor. Proceedings of the IEEE 51, 1190-1202 (1963)
Jaber-Ansari, L., Hahm, M. G., Somu, S., Sanz, Y. E., Busnaina, A. & Jung, Y. J. Mechanism of very large scale assembly of SWNTs in template guided fluidic assembly process. Journal of the American Chemical Society 131, 804-808 (2008)
Jia, Y., Wei, J., Wang, K., Cao, A., Shu, Q., Gui, X., Zhu, Y., Zhuang, D., Zhang, G. & Ma, B. Nanotube-silicon heterojunction solar cells. Advanced Materials 20, 4594-4598 (2008)
Jia, Y., Li, P., Gui, X., Wei, J., Wang, K., Zhu, H., Wu, D., Zhang, L., Cao, A. & Xu, Y. Encapsulated carbon nanotube-oxide-silicon solar cells with stable 10% efficiency. Applied Physics Letters 98, 133115-133115-133113 (2011)
Jia, Y., Cao, A., Bai, X., Li, Z., Zhang, L., Guo, N., Wei, J., Wang, K., Zhu, H. & Wu, D. Achieving high efficiency silicon-carbon nanotube heterojunction solar cells by acid doping. Nano letters 11, 1901-1905 (2011)
Kim, Y. L., Li, B., An, X., Hahm, M. G., Chen, L., Washington, M., Ajayan, P., Nayak, S. K., Busnaina, A. & Kar, S. Highly aligned scalable platinum-decorated single-wall carbon nanotube arrays for nanoscale electrical interconnects. ACS nano 3, 2818-2826 (2009)
Lee, K.-W., Noriki, A., Kiyoyama, K., Fukushima, T., Tanaka, T. & Koyanagi, M. Three-dimensional hybrid integration technology of CMOS, MEMS, and photonics circuits for optoelectronic heterogeneous integrated systems. Electron Devices, IEEE Transactions on 58, 748-757 (2011)
Li, Z., Kunets, V. P., Saini, V., Xu, Y., Dervishi, E., Salamo, G. J., Biris, A. R. & Biris, A. S. Light-harvesting using high density p-type single wall carbon nanotube/n-type silicon heterojunctions. ACS nano 3, 1407-1414 (2009)
Konstantatos, G.; Badioli, M.; Gaudreau, L; Osmond, J.; Bernechea, M.; Arquer, F.; Gatti, F.; Koppens, F.; Hybrid graphene quantum dot phototransistors with ultrahigh gain, Nature Nanotechnology 7, 363-368 (2012)
Kwon, Y.-K., Saito, S. & Tománek, D. Effect of intertube coupling on the electronic structure of carbon nanotube ropes. Physical Review B 58, R13314-R13317 (1998)
Liang, D., Roelkens, G., Baets, R. & Bowers, J. E. Hybrid integrated platforms for silicon photonics. Materials 3, 1782-1802 (2010)
Liu, L., Kumar, R., Huybrechts, K., Spuesens, T., Roelkens, G., Geluk, E.-J., de Vries, T., Regreny, P., Van Thourhout, D. & Baets, R. An ultra-small, low-power, all-optical flip-flop memory on a silicon chip. Nature Photonics 4, 182-187 (2010)
Liu, Y.; Clieng, C.; Liao, L.; Zhou, H.; Bai, .J.; Liu, G.; Liu, L.; Huang, Y.; Duan, X.; Plasmon resonance enhanced multicolour photodetection by graphene. Nature Communications. 2, 579 (2011)
Michel, J., Liu, J. & Kimerling, L. C. High-performance Ge-on-Si photodetectors. Nature Photonics 4, 527-534 (2010)
Muller, T.; Xia, F. N.; Avouris, P.; Graphene Photodetectors for high-speed optical communications. Nature-Photon. 4, 297-301 (2010)
Nair, R.; Blake, P.; Grigorenko, A.; Novoselov, K.; Booth, T; Stauber, T; Peres, N.; Geirn, A.; Fine Structure Constant Defines Visual Transparency of Graphene. Science 6, 1308 (2008)
Park, J.; Ahn, Y. H.; Ruiz-vargas, C.; Imaging of Pliotocurrent Generation and Collection in Single-Layer Graphene. Nano Lett. 9, 1742-1746 (2009)
Perdew, J. P. & Yue, W. Accurate and simple density functional for the electronic exchange energy: Generalized gradient approximation. Physical Review B 33, 8800 (1986)
Perdew, J. P., Burke, K. & Ernzerhof, M. Generalized gradient approximation made simple Physical review letters 77, 3865-3868 (1996)
Rong, H., Jones, R., Liu, A., Cohen, O., Hak, D., Fang, A. & Paniccia, M. A continuous-wave Raman silicon laser. Nature 433, 725-728 (2005)
Ruffieux, P., Gröning, O., Bielmann, M., Mauron, P., Schlapbach, L. & Gröning, P. Hydrogen adsorption on sp̂{2}-bonded carbon: Influence of the local curvature. Physical Review B 66, 245416 (2002)
Saito, R., Dresselhaus, G. & Dresselhaus, M. Trigonal warping effect of carbon nanotubes. Physical Review B 61, 2981 (2000), the method to calculate the 1D DoS of SWNTs has been utilized to create a freely available database at www.photon.t.u-tokyo.ac.jp/˜maruyama/kataura/1D_DOS.html.
Seidel, R., Graham, A. P., Unger, E., Duesberg, G. S., Liebau, M., Steinhoegl, W., Kreupl, F., Hoenlein, W. & Pompe, W. High-current nanotube transistors. Nano letters 4, 831-834 (2004)
Soler, J. M., Artacho, E., Gale, J. D., García, A., Junquera, J., Ordejón, P. & Sanchez-Portal, D. The SIESTA method for ab initio order-N materials simulation. Journal of Physics: Condensed Matter 14, 2745 (2002)
Stegeman, G., Hagan, D. & Tomer, L. χ (2) cascading phenomena and their applications to all-optical signal processing, mode-locking, pulse compression and solitons. Optical and Quantum electronics 28, 1691-1740 (1996)
Sze, S. M. & Ng, K. K. Physics of semiconductor devices. (Wiley-interscience, 2006) Sun, D.; Aivazian, Jones, A, M.; Ross, J. S.; Yao, W.; Cobden, D; Xu, X. D.; Ultrafast hot-carrier-dominated photocurrent in graphene, Nature Nanotech, 7, 114-118, (2012)
Troullier, N. & Martins, J. L. Efficient pseudopotentials for plane-wave calculations. Physical Review B 43, 1993 (1991)
Vasil'ev, V., Predein, A., Varavin, V., Mikha\check{i}lov, N., Dvoretski\check{i}, S., Reva, V., Sabinina, I., Sidorov, Y. G., Suslyakov, A. & Aseev, A. Linear 288×4-format photodetector with a bidirectional time-delay-and-storage regime. Journal of Optical Technology 76, 757-761 (2009)
Vlasov, Y. A., Bo, X.-Z., Sturm, J. C. & Norris, D. J. On-chip natural assembly of silicon photonic bandgap crystals. Nature 414, 289-293 (2001)
Vlasov, Y. A., O'Boyle, M., Hamann, H. F. & McNab, S. J. Active control of slow light on a chip with photonic crystal waveguides. Nature 438, 65-69 (2005)
Wang, J., Hu, J., Becla, P., Agarwal, A. M. & Kimerling, L. C. Resonant-cavity-enhanced mid-infrared photodetector on a silicon platform. Optics Express 18, 12890-12896 (2010)
Wadhwa, P., Liu, B., McCarthy, M. A., Wu, Z. & Rinzler, A. G. Electronic junction control in a nanotube-semiconductor Schottky junction solar cell. Nano letters 10, 5001-5005 (2010).
Wadhwa, P., Seol, G., Petterson, M. K., Guo, J. & Rinzler, A. G. Electrolyte-induced inversion layer Schottky junction solar cells. Nano letters 11, 2419-2423 (2011)
Wen, J., Guo, H., Xing, J., Lü, H., Jin, K.-J., He, M. & Yang, G. High-sensitivity photovoltage based on the interfacial photoelectric effect in the SrTiO3-δ/Si heterojunction. Science China Physics, Mechanics and Astronomy 53, 2080-2083 (2010)
Weis, S., Rivière, R., Deléglise, S., Gavartin, E., Arcizet, O., Schliesser, A. & Kippenberg, T. J. Optomechanically induced transparency. Science 330, 1520-1523 (2010)
Xia, F. N.; Mueller, T.; Lin, Y. M.; Garcia, A. V.; Avouris, P.; Ultrafast graphene photodetector. Nature Nanotech. 4, 839-843 (2009)
Xiong, X., Jaberansari, L., Hahm, M. G., Busnaina, A. & Jung, Y. J. Building Highly Organized Single-Walled-Carbon-Nanotube Networks Using Template-Guided Fluidic Assembly. Small 3, 2006-2010 (2007)
Xu, X.; Gabor, N. M.; Alden, J. S.; Zande, A, M; McEtten, P. L.; Photo-Thermoelectric Effect at a Graphene Interface Junction Nano Lett. 10, 562-566 (2010)

What is claimed is:

1. A heterojunction comprising one or more single-walled carbon nanotubes (SWNT) disposed on a first surface region of a p-doped Si material, the heterojunction capable of generating a photocurrent under reverse bias conditions.

2. The heterojunction of claim 1 comprising a second surface region of the p-doped Si material surrounding the first surface region, the second surface region covered by an insulating layer, wherein the SWNT extend from the first surface region onto the second surface region where they are separated from the p-doped Si material by the insulating layer.

3. The heterojunction of claim 2, wherein the SWNT are configured as a belt extending from the first surface region to the second surface region, the belt having a width in the range from about 0.1 mm to about 500 nm.

4. The heterojunction of claim 3, wherein said belt is attached to an electrical contact disposed on the insulating layer.

5. The heterojunction of claim 2, wherein the SWNT are configured as a patch overlaying said first surface region, the patch peripherally overlaying a portion of the second surface region.

6. The heterojunction of any of claims 2-5, wherein the insulating layer comprises silicon dioxide.

7. The heterojunction of claim 6, wherein the insulating layer has a thickness of from about 100 nm to about 400 nm.

8. The heterojunction of claim 1, wherein the photocurrent is generated in response to light incident on the SWNT, the light having a wavelength from about 300 nm to about 800 nm.

9. The heterojunction of claim 1, wherein the photocurrent is generated in response to light incident on the SWNT at an intensity of about 117 microwatts or less.

10. The heterojunction of claim 1, wherein the photocurrent is generated when a reverse bias voltage of from about 0.1 to about 3 volts is applied across the heterojunction.

11. The heterojunction of claim 10, wherein the photocurrent is only generated when a reverse bias voltage of from about 0.1 to about 3 volts is applied across the heterojunction.

12. The heterojunction of claim 1, wherein the Si is p-doped with boron at a level from about 10¹⁴ to about 10¹⁷ atom/cm³.

13. The heterojunction of claim 12, wherein the Si is doped with boron 10¹⁵ to about 10¹⁶ atom/cm³.

14. The heterojunction of any of the preceding claims, wherein the heterojunction is fabricated by a process comprising template-guided fluidic assembly.

15. A device comprising a heterojunction of any of the preceding claims, a first electrical contact connected to the SWNT, and a second electrical contact connected to the p-doped Si material, wherein an output current flowing between the first and second contacts and through the heterojunction is modulated by both an optical input and an electrical input.

16. The device of claim 15, wherein the electrical input is a reverse bias voltage applied between the first and second contacts.

17. The device of claim 15, wherein the optical input is light incident on the SWNT.

18. The device of claim 17 configured to accept the incident light from a solid state light emitter or a light guide.

19. The device of claim 15 that requires both an optical input and an electrical input to generate a photocurrent at the heterojunction.

20. The device of claim 19 that functions as a mixed optoelectronic AND gate.

21. The device of claim 15 comprising a plurality of said heterojunctions.

22. The device of claim 15 that functions as a 2-bit optoelectronic ADDER/OR gate, the device comprising first and second heterojunctions, wherein the first heterojunction is connected to the first electrical contact by a first SWNT belt and the second heterojunction also is connected to the first electrical contact by a second SWNT belt, wherein the first and second SWNT belts have essentially the same width and illumination of the first and/or second SWNT belts with application of a reverse bias between the first and second electrical contacts generates a photocurrent that is proportional to the total number of illuminated SWNT belts.

23. The device of claim 22 further comprising first and second solid-state lasers configured to illuminate said first and second SWNT belts, respectively.

24. The device of claim 15 that functions as a 4-bit optoelectronic digital-to-analog converter, the device comprising first, second, third, and fourth heterojunctions, wherein the first heterojunction is connected to the first electrical contact by a first SWNT belt, the second heterojunction also is connected to the first electrical contact by a second SWNT belt, the third heterojunction also is connected to the first electrical contact by a third SWNT belt, and the fourth heterojunction also is connected to the first electrical contact by a fourth SWNT belt, wherein the second SWNT belt has a width essentially two times the width of the first SWNT belt, the third SWNT belt has a width essentially four times the width of the first SWNT belt, and the fourth SWNT belt has a width essentially eight times the width of the first SWNT belt, and wherein illumination of the first and/or second and/or third and/or fourth SWNT belts and application of a reverse bias between the first and second electrical contacts generates a photocurrent that is proportional to the total width of the illuminated SWNT belts.

25. The device of claim 24 further comprising first, second, third, and fourth solid-state lasers configured to illuminate said first, second, third, and fourth SWNT belts, respectively.

26. The device of claim 15 that functions as a bidirectional phototransistor, the device comprising a plurality of first heterojunctions and a plurality of second heterojunctions disposed on a common p-doped Si surface, wherein the first heterojunctions are connected via a first SWNT belt set to a first electrical contact disposed on a first insulating layer on a first side of the common p-doped Si surface and the second heterojunctions are connected via a second SWNT belt set to a second electrical contact disposed on a second insulating layer on a second side of the common p-doped Si surface, the first and second insulating layers disposed opposite to each other, wherein the first and second SWNT belt sets are disposed in an interdigitated configuration on the common p-doped Si surface, wherein illumination of the first and second SWNT band sets and application of a bias between the first and second electrical contacts produces a photocurrent.

27. The device of claim 26, wherein the photocurrent is modulated by the illumination intensity.

28. The device of claim 26 further comprising a light source configured to illuminate the first and second heterojunctions.

29. A compound device comprising a plurality of individual devices of any of claims 15-28 on a single chip.

30. The compound device of claim 28, wherein the plurality of devices are configured as an array.

31. The compound device of claim 29 that functions as an image sensor.

32. The compound device of claim 30, wherein the array is about 12 mm×12 mm in size and contains about 250,000 of said devices.

33. The compound device of claim 19, wherein individual devices have dimensions of about 15 μm×15 μm.

34. A method of fabricating the heterojunction of claim 1, the method comprising the steps of:
(a) providing a p-doped Si substrate having a surface covered with an insulating layer;
(b) producing one or more first surface regions of exposed p-doped Si by selectively removing the insulating layer using lithography and a second surface region surrounding each first surface region, the second surface regions retaining the insulating layer;
(c) etching the first and second surface regions using a plasma, whereby the first and second surface regions become hydrophilic;
(d) depositing a hydrophobic mask layer over the first and second surface regions;
(e) patterning the hydrophobic mask layer by lithography, whereby one or more microscale or nanoscale trenches or patches are formed;
(f) submerging the substrate in an suspension of SWNT;
(g) withdrawing the substrate up through the SWNT suspension, whereby SWNT are selectively deposited in the trenches or patches to form one or more heterojunctions between the deposited SWNT and the first surface regions of p-doped Si; and optionally removing the hydrophobic mask layer.

35. The method of claim 34, further comprising:
(h) depositing a first electrical contact in ohmic connection with the deposited SWNT in the second surface region and a second electrical contact in ohmic connection with the p-doped Si in the first surface region.

36. The method of claim 35, wherein the first and second electrical contacts comprise one or more metals selected from the group consisting of gold, titanium, and combinations thereof.

37. The method of claim 34, wherein the hydrophobic mask comprises poly(methyl methacrylate).

38. The heterojunction of any of claims 1-14, wherein the SWNT are semiconducting.

39. The device of any of claims 15-28, wherein the SWNT are semiconducting.

40. The heterojunction of any of claims 1-14, wherein a single SWNT is used to form the heterojunction.

41. The heterojunction of any of claims 1-14, wherein a plurality of SWNT are used to form the heterojunction.

42. The device of any of claims 15-28, wherein a single SWNT is used to form the heterojunction of the device.

43. The device of any of claims 15-28, wherein a plurality of SWNT are used to form the heterojunction of the device.
